(19) United States
(12) Patent Application Publication
(10) Pub. No.: US 2026/0299228 A1
(43) Pub. Date: Oct. 1, 2026

(54) NEXT GENERATION FIBER OPTIC MODULE

(71) Applicants: James Jonathan Farquhar, Tanjung Tokong (MY); Lye Boon Teng, Bayan Lepas (MY); Arvind Murugan, Bayan Lepas (MY); Sharvin Murugan, Bayan Lepas (MY); Muhammad Afiq Bin Nasiruddin, Gelugor (MY)

(72) Inventors: James Jonathan Farquhar, Tanjung Tokong (MY); Lye Boon Teng, Bayan Lepas (MY); Arvind Murugan, Bayan Lepas (MY); Sharvin Murugan, Bayan Lepas (MY); Muhammad Afiq Bin Nasiruddin, Gelugor (MY)

(21) Appl. No.: 19/093,104

(22) Filed: Mar. 27, 2025

(51) Int. Cl. G02B 6/42; H05K 7/20

(52) U.S. Cl. CPC G02B 6/4262; G02B 6/423; G02B 6/4251; G02B 6/4261; G02B 6/4267; G02B 6/4269; G02B 6/4275; G02B 6/4277; H05K 7/20145; G02B 6/4257

(57) ABSTRACT

The present disclosure is directed to a fiber optic module constructed with a housing that includes an upper housing and a lower housing. The device also includes a release mechanism that is operated with a spring loaded release tab. At least one plastic element is provided to aid alignment of the electronic components used in the fiber optic module. The fiber optic module also includes at least one thermal transfer device adapted to remove heat from the fiber optic module. The thermal transfer device is typically mounted in an opening in the lid. The thermal transfer device may also include a plurality of upright fins with spaces between the fins. In various embodiments, a heat dissipating material is placed in the spaces between the fins of the thermal transfer device.

### CROSS REFERENCE TO RELATED APPLICATIONS

N/A

### FIELD OF THE PRESENT DISCLOSURE

The present disclosure teaches structures for fiber optic modules, and more specifically is an improved fiber optic module with improved heat transfer and structural integrity characteristics.

### SUMMARY

Disclosed herein is a fiber optic module housing including an upper housing, a lower housing, a release mechanism and thermal transfer devices. At least one moldable element is provided to aid in the alignment of the optical sub-assembly (OSA) and at least one printed circuit board assembly (PCBA), and to align and retain the optical interface, electrical interface and at least one thermal transfer device (TTD). The thermal transfer device is typically mounted in an opening in the lid or on the top of the package. The thermal transfer device may also include a plurality of upright fins with spaces between the fins. In various embodiments, a heat dissipating material structure is placed in the spaces between the fins of the thermal transfer device. The release mechanism is operated with a built-in spring loaded release tab. The upper and lower housing elements of the housing includes distinct materials specifically chosen to provide alignment features, maximum thermal dissipation emi/esd (electromagnetic interference/electrostatic discharge) protection, increased available internal volume, and superior structural strength.

### BRIEF DESCRIPTION OF THE DRAWINGS

The accompanying drawings, where like reference numerals refer to identical or functionally similar elements throughout the separate views, together with the detailed description below, are incorporated in and form part of the specification, and serve to further illustrate embodiments of concepts that include the claimed disclosure, and explain various principles and advantages of those embodiments.

The methods and systems disclosed herein have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

FIG. 1 is a perspective view of an embodiment of a Fiber optic module according to the present disclosure.

FIG. 1A is an exploded view of the Housing's, Upper housing, Slide release mechanism, Lower housing and Thermal Transfer Device (TTD) as illustrated in FIG. 1.

FIG. 1B is a top plane view of the Housing as illustrated in FIG. 1A.

FIG. 1C is a top perspective view of the Housing with a side walls of the Housing broken to show the overlapping elements labeled A-A in FIG. 1B.

FIG. 1D is a detailed view of the circled area labeled B in FIG. 1C.

FIG. 2 is an exploded view of the Housing illustrated in FIG. 1A.

FIG. 3 is a top perspective view of the Upper housing as illustrated in FIG. 1A.

FIG. 3A is an exploded view of the Upper housing in FIG. 3.

FIG. 3B is a top perspective view of the UH sheet metal and Finned heat sink components of FIG. 3 inserted into a mold.

FIG. 3C is a top perspective view of the UH sheet metal, Finned heat sink with the UH moldable interior structure molded into the Upper housing assembly of FIG. 3.

FIG. 4 is a perspective view of the Lower housing element of FIG. 1A.

FIG. 4A is an exploded view of FIG. 4.

FIG. 4B is a top perspective view of the LH sheet metal and Solid heat sink components of FIG. 4A inserted into a mold.

FIG. 4C is a perspective view of the LH sheet metal, Solid heat sink with the LH moldable interior structure element molded into the Lower housing assembly of FIG. 4.

FIG. 5 is a top plane view of the Fiber optic module of FIG. 1 inserted into a Port/Cage.

FIG. 5A is a top perspective view of FIG. 5 with a side wall of the Port/Cage broken to show the interlocking elements labeled C-C in FIG. 5.

FIG. 5B is a detailed view of the area circled and labeled D in FIG. 5A, showing a Slide release mechanism that acts to remove the Fiber optic module from a Port/Cage.

FIG. 5C is a perspective view of the Lower housing and Slide release mechanism of FIG. 1A.

FIG. 5D is a detailed view of the rectangle area and labeled E in FIG. 5C

FIG. 5E is a detailed view of the area circled and labeled F in FIG. 5C

FIG. 5F is a detailed view of the area circled and labeled G in FIG. 5C

FIG. 5G is a detailed view of the area circled and labeled H in FIG. 5C

FIG. 5H is a perspective view of FIG. 5

FIG. 5J is a detailed view of the area circled and labeled J in FIG. 5H

FIG. 5K is a detailed view of the area circled and labeled K in FIG. 5H

FIG. 6 is a Top plane view of FIG. 1.

FIG. 6A is a sectional view taken along the L-L section line in FIG. 6.

FIG. 6B is a detailed view of the area circled and labeled M in FIG. 6A

FIG. 6C is a detailed view of the area circled and labeled N in FIG. 6A

FIG. 7 is a bottom plane view of an embodiment of a Fiber optic module showing a Mechanical fastener.

FIG. 7A is a bottom perspective view of the Fiber optic module partially broken along section line P-P of FIG. 7 to show a mechanism to fasten the elements of the Fiber optic module together.

FIG. 7B is a detailed view of the area circled and labeled Q in FIG. 7A.

FIG. 8 is a top plane view of an embodiment of a Fiber optic module showing an Adhesive bonding method.

FIG. 8A is a sectional view along line R-R in FIG. 8 showing fastening of the Upper housing to the Lower housing with an Adhesive.

FIG. 8B is a detailed view of the circled areas labeled S1 and S2 in FIG. 8A

FIG. 9 is a top plane view of an embodiment of a Fiber optic module showing a mechanical Crimp bonding method.

FIG. 9A is a sectional view of the Fiber optic module along line T-T in FIG. 9. showing fastening of the Upper housing to the Lower housing with an mechanical Crimp

FIG. 9B is a detailed view of the circled area labeled U in FIG. 9A.

FIG. 10 is a top plane view of an embodiment of a Fiber optic module showing an Energy director Ultrasonic weld process.

FIG. 10A is a sectional view of the Fiber optic module along line V-V in FIG. 10. showing fastening of the Upper housing to the Lower housing with an Energy director for Ultrasonic weld process.

FIG. 10B is a detailed view of the circled area labeled W in FIG. 10A prior to the Ultrasonic weld process.

FIG. 10C is a detailed view of the circled area labeled X in FIG. 10A after the Ultrasonic weld process.

FIG. 10D is a top plane view of an embodiment of a Fiber optic module showing a Shear weld Ultrasonic weld process.

FIG. 10E is a sectional view of the Fiber optic module along line Y-Y in FIG. 10D.

FIG. 10F is a detailed view of the circled area labeled Z in FIG. 10E prior to the Ultrasonic weld process.

FIG. 10G is a detailed view of the circled area labeled AA in FIG. 10E after the Ultrasonic weld process.

FIG. 10H is a top plane view of an embodiment of a Fiber optic module showing a Laser weld process.

FIG. 10J is a sectional view of the Fiber optic module along line AB-AB in FIG. 10H.

FIG. 10K is a detailed view of the circled area labeled AC in FIG. 10J after the Laser weld process.

FIG. 11 is a top plane view of an embodiment of a Fiber optic module with a Coplanar TTD

FIG. 11A is a sectional view of the Fiber optic module along line AD-AD in FIG. 11.

FIG. 11B is a detailed view of the circled area labeled AE in FIG. 11A showing a method of affixing a Coplanar TTD.

FIG. 12 is a top plane view of an embodiment of a Fiber optic module showing a Finned heat sink enhanced with Metal foam.

FIG. 12A is a sectional view of the Fiber optic module along line AF-AF in FIG. 12.

FIG. 12B is a detailed view of the circled area labeled AG in FIG. 12A

FIG. 13 is a top plane view of an embodiment of a Fiber optic module showing a Vertical and Planar, Thermal vacuum chamber TTD.

FIG. 13A is a sectional view of the Fiber optic module along line AH-AH in FIG. 13.

FIG. 13B is a detailed view of the circled area labeled AJ in FIG. 13A.

FIG. 13C is a detailed view of the circled area labeled AK in FIG. 13B.

FIG. 13D is a top plane view of an embodiment of a Fiber optic module showing a Horizontal cooling fin added to a Vertical thermal vacuum chamber

FIG. 13E is a sectional view of the Fiber optic module along line AL-AL in FIG. 13D.

FIG. 13F is a detailed view of the rectangular area labeled AM in FIG. 13E.

FIG. 14 is a bottom perspective view of the Upper housing illustrated in FIG. 1A. showing added molded LSR Hermetic/Environmental seals.

FIG. 14A is a Top perspective view of the Lower housing illustrated in FIG. 1A. showing added molded LSR Hermetic/Environmental seals.

FIG. 14B is a Top plane view of an embodiment of a Fiber optic module.

FIG. 14C is a sectional view of the Fiber optic module along line AN-AN in FIG. 14B.

FIG. 14D is a detailed view of the circled area labeled AP in FIG. 14C.

FIG. 14E is a bottom perspective view of an embodiment of an Upper housing showing an added TIM containment molded feature.

FIG. 14F is a top plane view of an embodiment of Fiber optic module comprising of FIG. 14E

FIG. 14G is a sectional view of the Fiber optic module along line AQ-AQ in FIG. 14F.

FIG. 14H is a detailed view of the circled area labeled AR in FIG. 14G. after assembly at room temperature.

FIG. 14J is a detailed view of the circled area labeled AS in FIG. 14G.

FIG. 14K is a detailed view of the circled area labeled AT in FIG. 14G.

FIG. 14L is a bottom perspective view of an embodiment of an Upper housing showing an added EMI/ESD gasket.

FIG. 14M is a top perspective view of an embodiment of a Lower housing showing an added EMI/ESD gasket.

FIG. 14N is a top plane view of an embodiment of a Fiber optic module comprising of FIG. 14L and FIG. 14M.

FIG. 14P is a sectional view of the Fiber optic module along line AU-AU in FIG. 14N.

FIG. 14Q is a detailed view of the circled area labeled AV in FIG. 14P.

FIG. 15 is a flow chart of one process used to create a non-machined hydraulically formed finned TTD.

FIG. 16 is a flow chart illustrating the process to add copper foam to the Fiber optic module housing to provide an amplified surface area to facilitate increased heat dissipation or heat transfer.

### DETAILED DESCRIPTION

The present disclosure teaches a fiber optic module housing 11 that includes an exterior shell integrally from sheet metal. The sheet metal includes at least one fold line that may define an exterior surface establishing outer dimensions of the housing. The exterior shell provides structural integrity, facilitates manufacturability, and may include mechanical interlocking features configured to establish a mechanical bond with an interior geometry and/or other assembly components. The exterior shell, or exoskeleton, includes at least one structural material selected from metals, metal alloys, composites, metal cladding, or combinations thereof. The exoskeleton is formed with an interior three-dimensional geometry that may be formed integrally within said exoskeleton by forming a material within an interior region of the exoskeleton.

The interior three-dimensional geometry of the exoskeleton defines features configured to securely position, align, and retain elements or components of the module. The components may include an optical sub-assembly, one or more inter-connection mechanisms, one or more thermal transfer devices, one or more electronic components, one or more optical components, and at least one printed circuit board assembly (PCBA).

The material forming process within the interior of the housing 11 may include injecting or otherwise applying a moldable material into the interior region of the exoskeleton. The moldable material used in the material forming process undergoes a phase change from a liquid or semi-solid state into a solid state upon curing or solidification. The forming process may include forging a solid or semi-solid metal directly into mechanical engagement with the mechanical interlocking features of the exoskeleton. The exoskeleton may also include an integrated thermal transfer device.

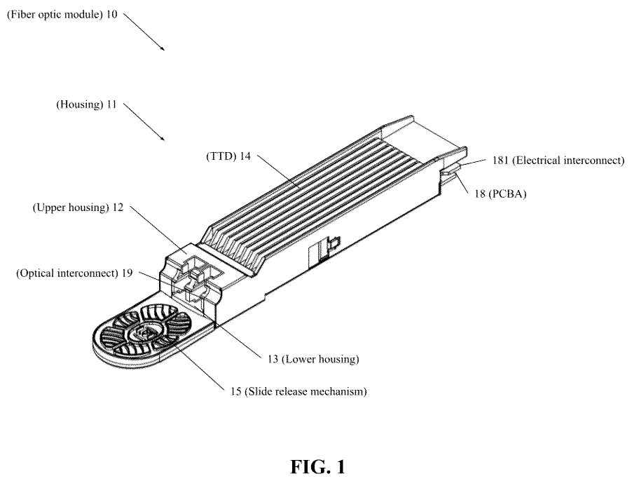

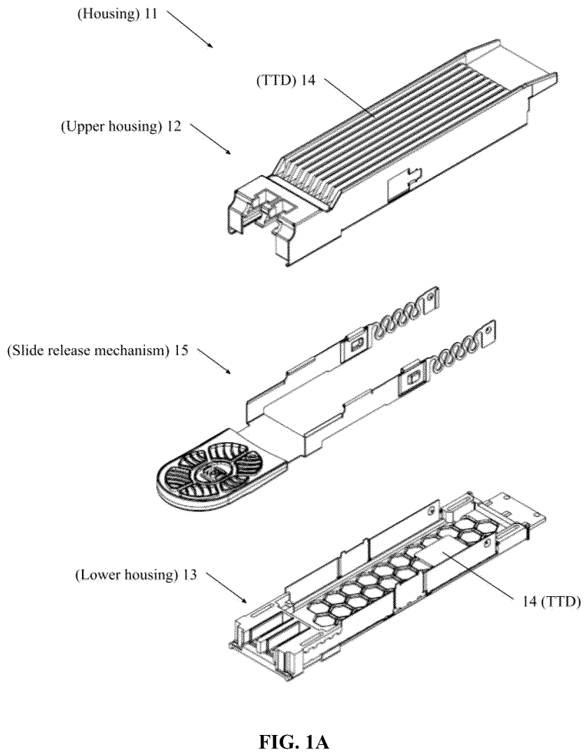

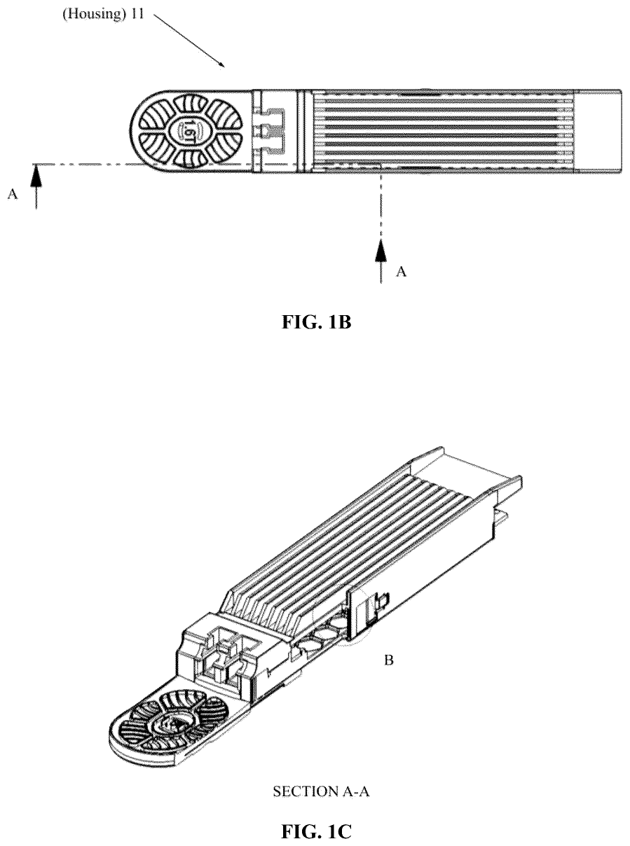

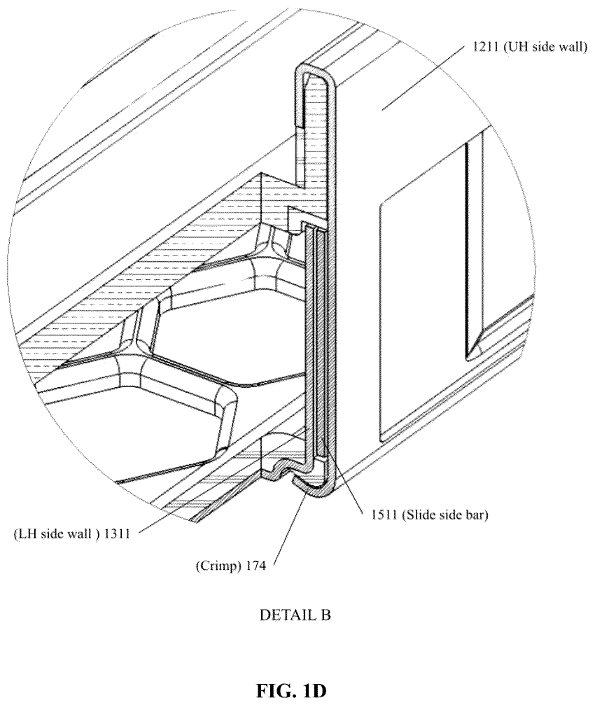

Referring now to FIG. 1 and FIG. 1A, the present disclosure describes an improved fiber optic module 10, which includes a housing 11. The housing 11 is typically formed with an upper housing 12 (UH) and a lower housing 13 (LH), and a slide release mechanism 15. The module 10 may include one or more TTDs 14. The TTDs 14 may be affixed to or formed integrally with either or both of the UH 12 and the LH 13.

The fiber optic module 10 also includes an attendant printed circuit board assembly (PCBA 18) that controls the fiber optical/electronic transceiver functions, optical interconnect 19, electrical interconnect 181 or similar components essential to the functioning of the module 10.

FIG. 1B is a top plane view of the housing 11. FIG. 1C is a sectional view along the line A-A in FIG. 1B, FIG. 1D is a detailed view of the circled area labeled B in FIG. 1C. The UH side walls 1211 overlap LH side walls 1311, forming a crimp 174. The UH side walls 1211 and the LH side walls 1311 sandwich the slide side bars 1511 of the slide release mechanism 15. This structure forms three layers of electromagnetic interference/electrostatic discharge (EMI/ESD) protection for the electronic components. The layers may include multiple different materials. The superior EMI/ESD shielding eliminates the need to provide form in place (FIP) gaskets to shield the electronics of the Fiber optic module 10.

An embodiment of Housing 11 is shown in the exploded view of FIG. 2. where the Housing 11 is constructed from at least two different materials: an external structure UH sheet metal 121 or LH sheet metal 131 composed of sheet metal, which may include stainless steel alloys, copper, copper alloys, aluminum, aluminum alloys, or stainless steel with copper, copper alloy, aluminum, or aluminum alloy cladding and further comprises an internal structure UH moldable interior structure 122 or LH moldable interior structure 132 consisting of a molded polymer, metal, or composite material, such as liquid crystal polymer (LCP), thermoplastic polymer, or thermosetting resin, may also serve as a thermal isolation barrier and may be configured to provide structural support and alignment for internal components. The material selection for any of UH moldable interior structure 122 or LH moldable interior structure 132 is intentional and optimized to reduce thermal conductivity, thereby limiting heat transfer between critical components within the Fiber optic module 10.

By incorporating a thermally isolating polymer or composite material, the design of Fiber optic module 10 effectively prevents unintended heat dissipation into temperature-sensitive areas, such as optical components, electrical circuits, or heat-sensitive adhesives. The inclusion of thermally isolative materials further mitigates thermal stress-induced deformation, enhancing long-term operational reliability. Additionally, the internal structure may function as an EMI/ESD protective barrier, thereby optimizing the module's performance in high-speed data transmission applications.

The combination of a thermally isolative internal structure and a conductive external housing provides a targeted thermal management solution, ensuring controlled heat dissipation only in designated regions while minimizing unintended thermal transfer, thereby improving overall module efficiency and longevity.

The Housing 11 may also include one or more heat-dissipating TTD 14, such as solid or finned heat sinks, heat spreaders, thermal vapor chambers, or thermally conductive interface layers, strategically placed to direct heat away from critical electronic components while maintaining the thermal isolation properties of the internal structure.

Furthermore, solid, finned, or coplanar TTD 14 may be formed by rolling, hydraulic forming, and/or forging processes, thereby reducing material waste and lowering processing costs compared to conventional methods such as machining, extrusion, or stamping, while producing a denser, more accurate, and repeatable component.

By utilizing the moldable interior structures materials' relatively low temperature melt range for liquid-to-solid phase change compared to the precision stamped external structure and thermal transfer device, the moldable material can flow into the Housing 11, conform around components/features as a liquid/near liquid, and mechanically bind them during solidification. This process may create additional geometry that could align, fasten, and mount other components during assembly.

Features incorporated on the UH sheet metal 121 and/or LH sheet metal 131 the TTD 14 or additional components may mechanically interlock by the solidified moldable interior structure's material.

The moldable interior structure's material may be compounded with metal flakes or micro metal powder to absorb and reflect EMI/ESD emissions, disrupting EMI/ESD from propagating along the Housing 11 metallic surfaces. This eliminates the need for form-in-place (FIP) gasket materials and reduces the number of processes and components.

A high thermal conductor for the TTD 14 is integrated directly into the Housing 11 by the insert molding and/or mechanically capturing processes by the moldable interior structure's material together with the precision stamped exoskeleton structure, with a low thermal resistance between the heat source on the PCBA 18's high-wattage ICs and the TTD 14's exterior, ensuring efficient heat dissipation. The TTD 14 may incorporate a compartment built around the EMI emitting component to further enhance the EMI absorption and dissipation.

The UH moldable interior structure 122 and/or the LH moldable interior structure 132 may have a structure with singular or multiple openings that facilitate heat dissipation.

The UH moldable interior structure 122 limits the expansion and contraction of the Fiber optic module 10 during operation, when the temperature of the Fiber optic module 10 fluctuates. The UH moldable interior structure 122, as with all the plastic elements in the housing, may be treated with plasma vapor deposition to make the non-conductive materials conductive, which provides still better EMI/ESD shielding.

The slide release mechanism 15 includes a slide sheet metal 151 that enhances the EMI/ESD shielding protection for the components as described above. The slide side bars 1511 of the slide release mechanism 15 include built-in spring returns 1513. The slide release mechanism 15 may be preassembled to the lower housing 13. Distal ends of the spring returns 1513 include spring retainers 1514 and slide dimples 1515. The spring retainers 1514 may interlock with the dimples 113 to secure the slide release mechanism 15 in its proper position in the fiber optic module 10. The slide release mechanism 15 also includes extended/retracted stops 1516 and alignment guides 1517. The slide side bars 1511 of the slide release mechanism 15 each further include a cam 1512 that is received in a cam recess 112 in the LH side walls 1311.

It should be noted that the spring returns 1513 are integral to the slide side bars 1511 of the slide release mechanism 15. The slide release mechanism 15 is formed by a stamping process. The metal material is stamped to form the spring returns 1513 without the need for any further processing. This significantly reduces manufacturing complexity and cost.

An overmold pull tab 152 is configured to pull the slide release mechanism 15 from a mating port (the port including the associated cage, edge connector, and any auxiliary accessories such as additional TTDs).

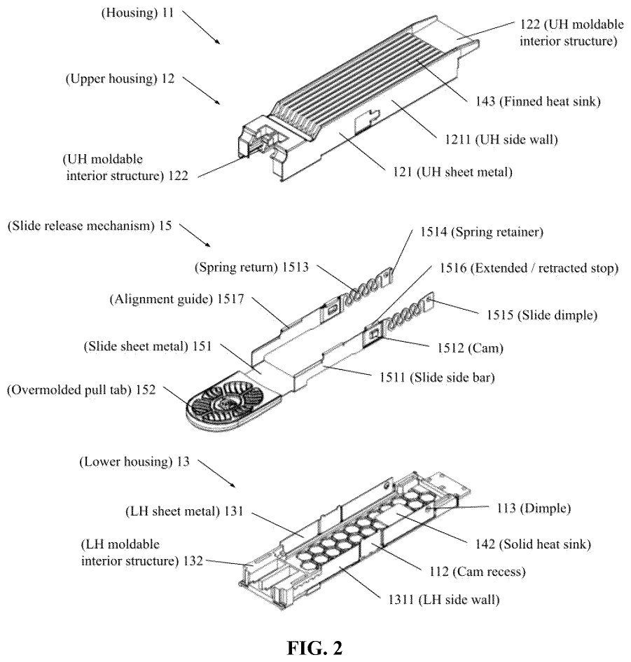

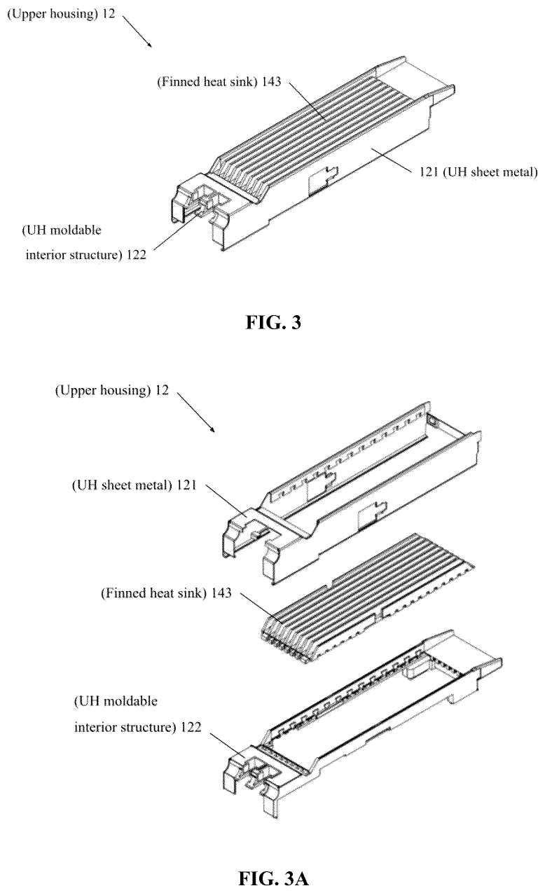

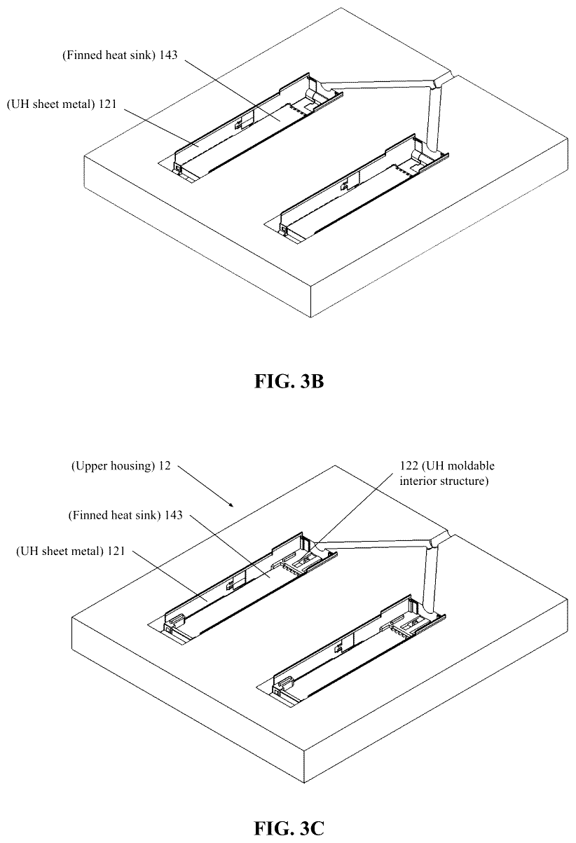

FIG. 3 is an embodiment of a top perspective view of the Upper housing 12, showing elements UH sheet metal 121, UH moldable interior structure 122 and an optional Finned heat sink 143 as an assembly.

FIG. 3A is an embodiment of an exploded perspective view of the Upper housing 12, showing elements UH sheet metal 121, UH interior moldable structure 122 and an optional Finned heat sink 143.

FIG. 3B is a perspective view of an embodiment showing the UH sheet metal 121 an optional Finned heat sink 143 inserted in preparation for the molding process.

FIG. 3C is a perspective view illustrating Upper housing 12 as an insert molded assembly of the UH sheet metal 121 and an optional Finned heat sink 143 bonded by the UH moldable interior structure 122 with the geometry for alignment already defined.

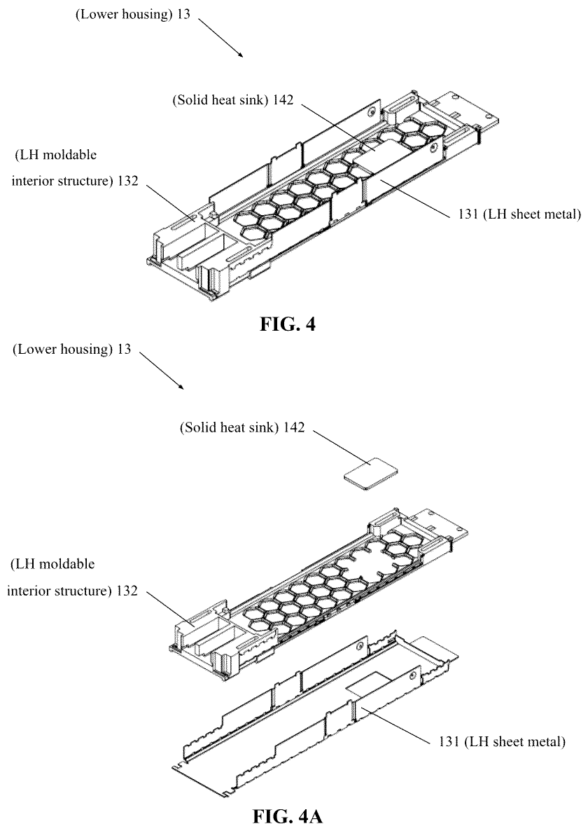

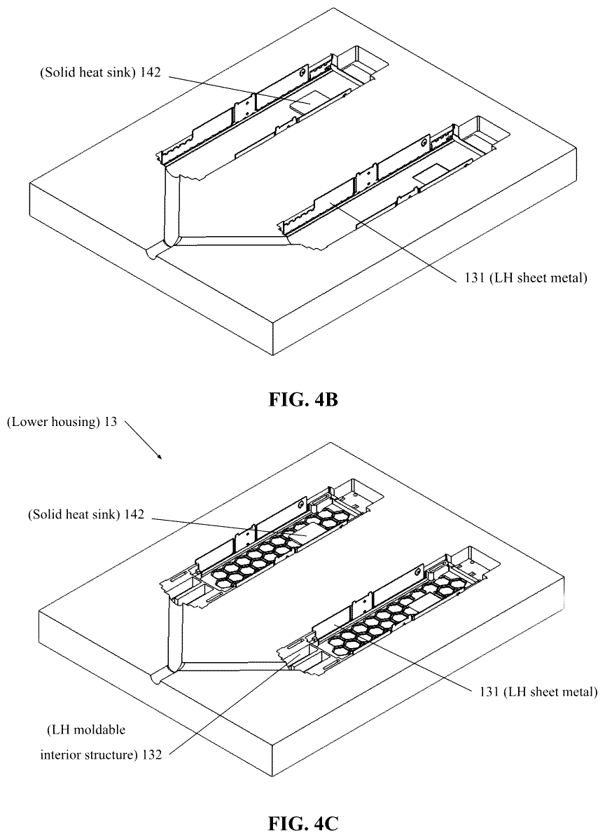

FIG. 4 is a top perspective view of an embodiment of the Lower housing 13, showing elements of the LH sheet metal 131, LH moldable interior structure 132 and optional Solid heat sink 142 as an assembly.

FIG. 4A is a top exploded view of an embodiment of the Lower housing 13, comprising a LH sheet metal 131, LH moldable interior structure 132, optional Solid heat sink 142.

FIG. 4B is a perspective view showing an embodiment of the LH sheet metal 131 an optional Solid heat sink 142 inserted in preparation for the molding process.

FIG. 4C is a perspective view illustrating an embodiment of Lower housing 13 as an insert molded assembly of the LH sheet metal 131 an optional Solid heat sink 142 bonded by the LH moldable interior structure 132 with the geometry for alignment already defined.

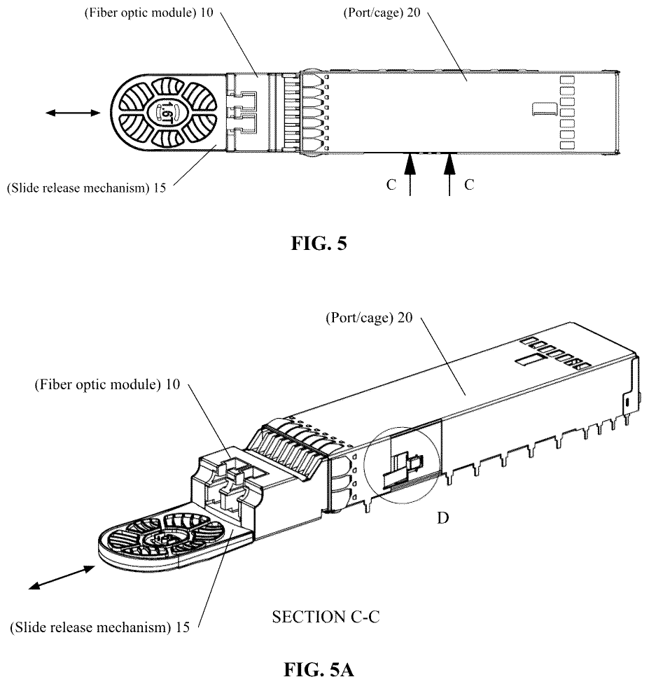

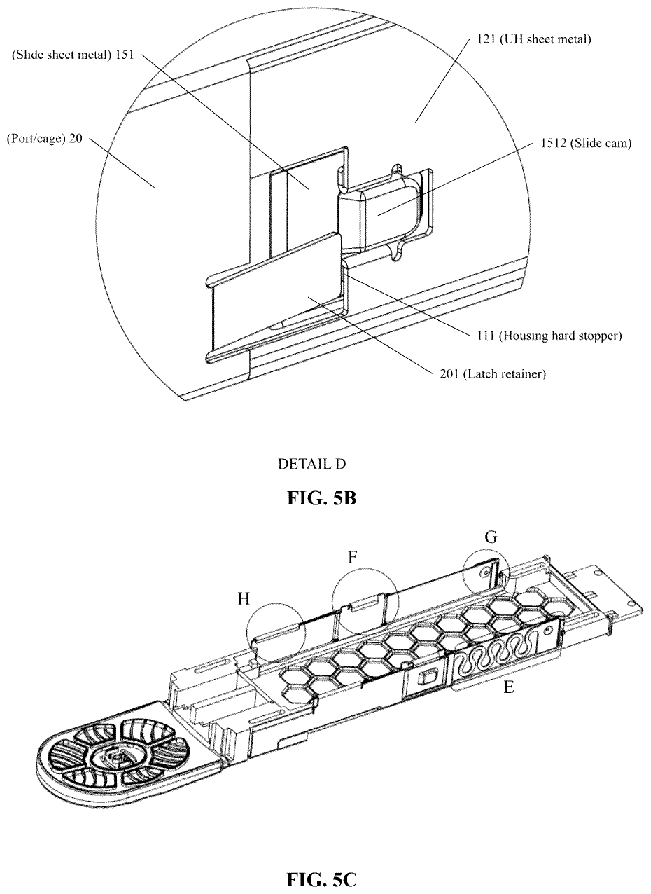

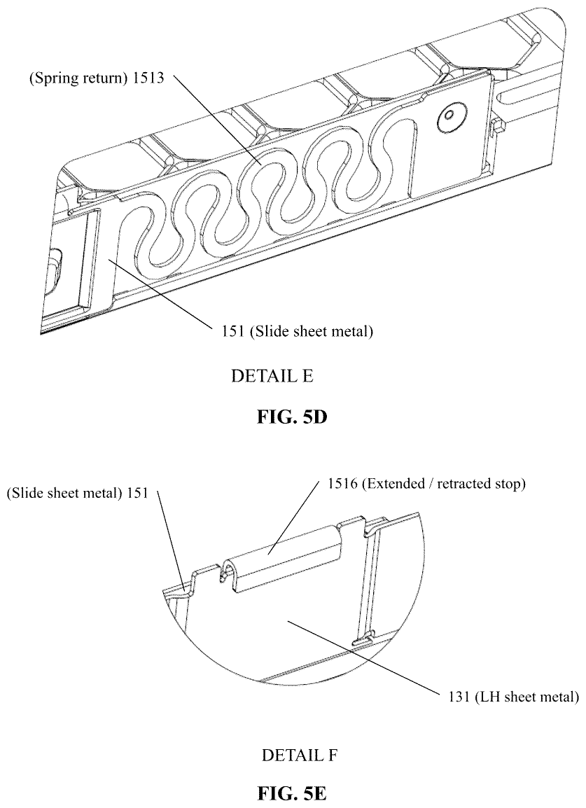

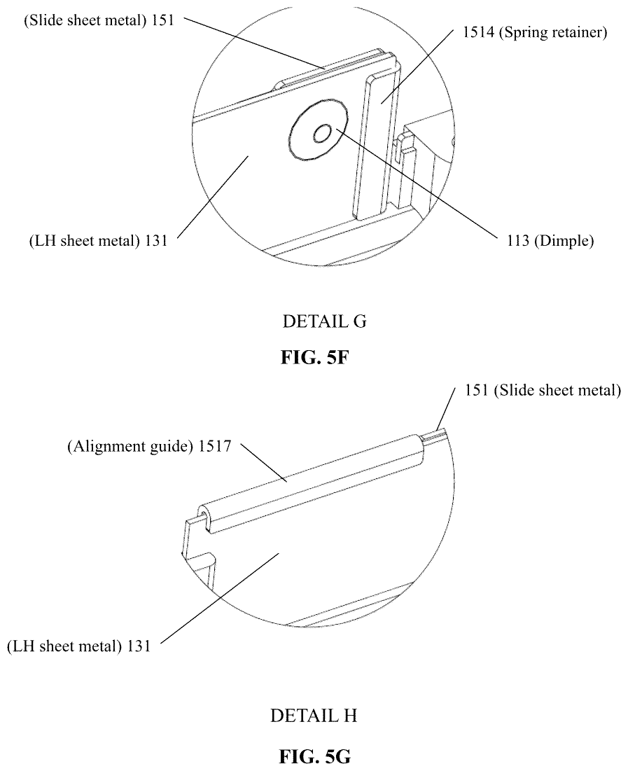

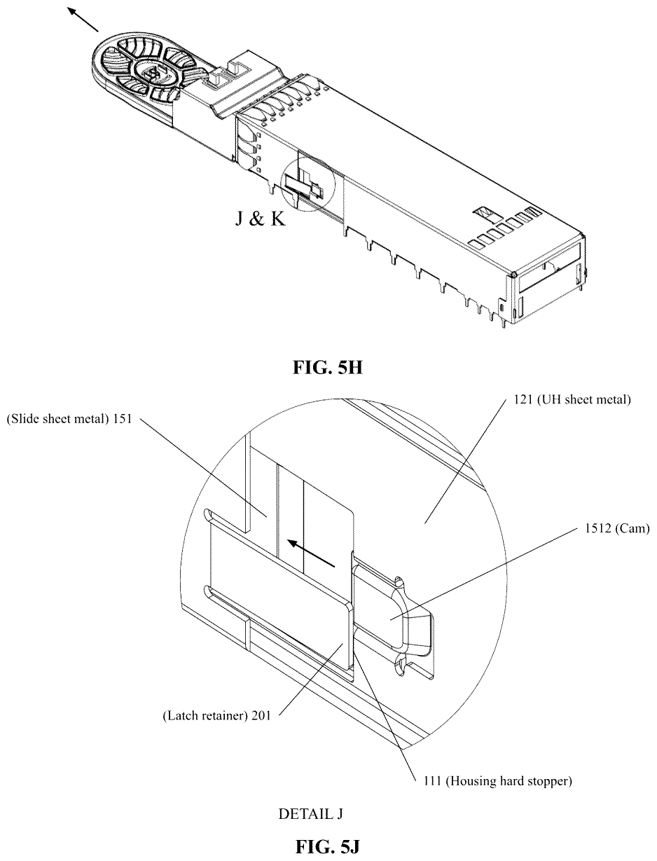

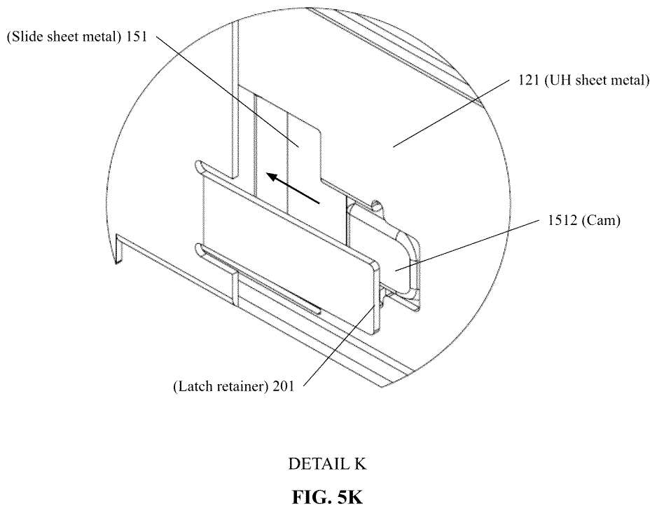

FIG. 5 through FIG. 5K show elements of a mechanism by which the Fiber optic module 10 is secured in the Port/Cage 20. Latch retainer 201 on the Port/Cage 20 latching the Fiber optic module 10 to the Housing hard stopper 111. When the release mechanism's Slide sheet metal 151 is pulled, the Slide cam 1512 will lift the Latch retainer 201 releasing the Fiber optic module 10 from the Port/Cage 20.

FIG. 5B shows a Fiber optic module 10 latched in the Port/Cage 20,

FIG. 5J shows the Fiber optic module 10 Cam 1512 releasing from the Port/Cage 20.

FIG. 5K shows a Fiber optic module 10 free to insert or remove from the Port/Cage 20.

FIG. 5E detail F shows the Slide release mechanism 15 element Extended/retracted stops 1516 prevent the over/under stroke of the Slide release mechanism 15.

FIG. 5G detail H shows how the element Alignment guide 1517 feature in the Slide Sheet Metal 151 guides along LH sheet metal 131 to compensate cantilevered pull on the Slide release mechanism 15.

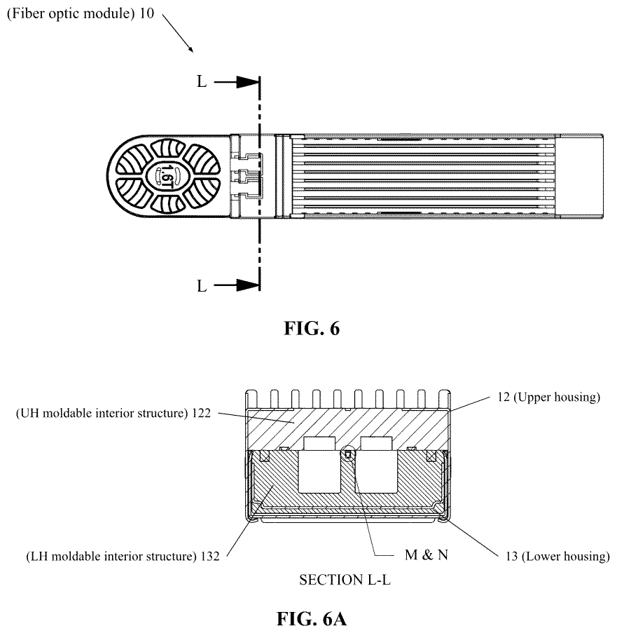

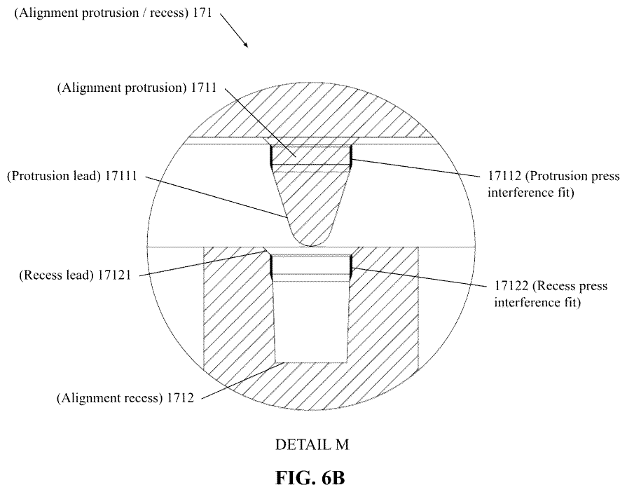

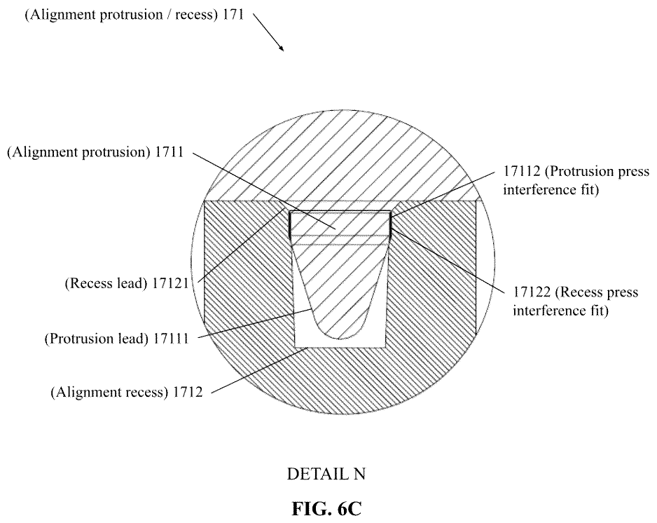

FIG. 6. through FIG. 6B show an embodiment of the fiber optic module 10 which may include at least one alignment protrusion/recess 171 which helps to ensure proper alignment of the components in the fiber optic module 10. The upper housing 12 or the lower housing 13 features a mating alignment protrusion 1711 and an alignment recess 1712 in either the UH moldable interior structure 122 or the LH moldable interior structure 132, and housing an alignment protrusion 1711 feature that includes a protrusion lead 17111 and a protrusion press interference fit 17112 and where the alignment recess 1712 feature includes a recess lead 17121 and an recess press interference fit 17122. FIG. 6C illustrates the housing compressed together to provide a prefastened assembly.

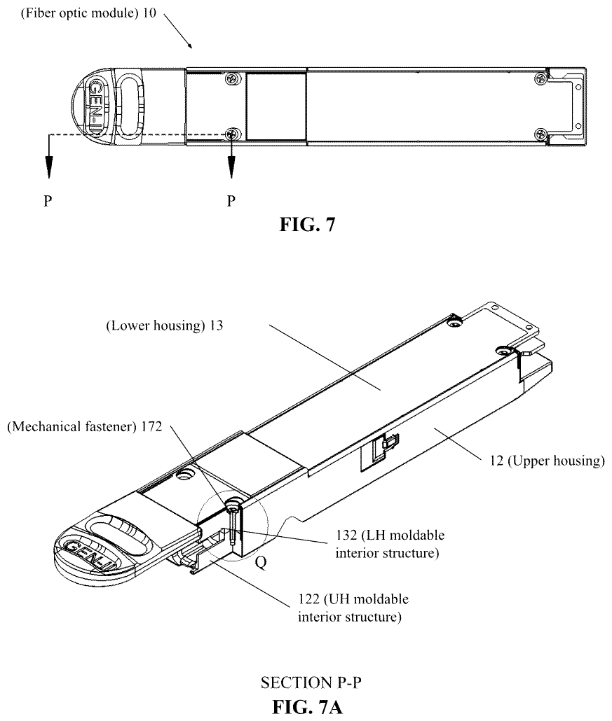

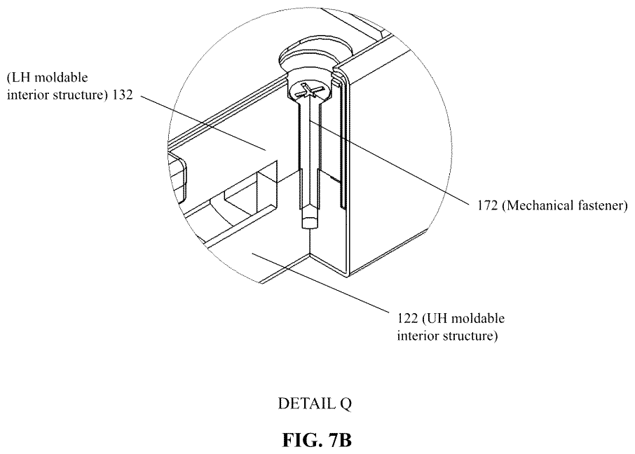

FIG. 7 is a bottom plane view of an embodiment of fiber optic module 10. FIG. 7A is a sectional view along line P-P in FIG. 7. FIG. 7B is a detailed view of the circled area labeled Q in FIG. 7A showing a mechanical fastener 172, in this instance a screw, that may be used to secure the upper housing 12 to the lower housing 13. FIGS. 7A an 7B also illustrate the features that may typically be used for the mechanical fastener interface in the UH interior moldable structure 122 or the LH interior moldable structure 132, like clearance for a screw head and thread and a threaded feature on the mating side. At least one of the mechanical fasteners 172 may be used to secure the upper housing 12 to the lower housing 13. Other applicable mechanical fasteners may be rivets, self tapping fasteners, etc. . . .

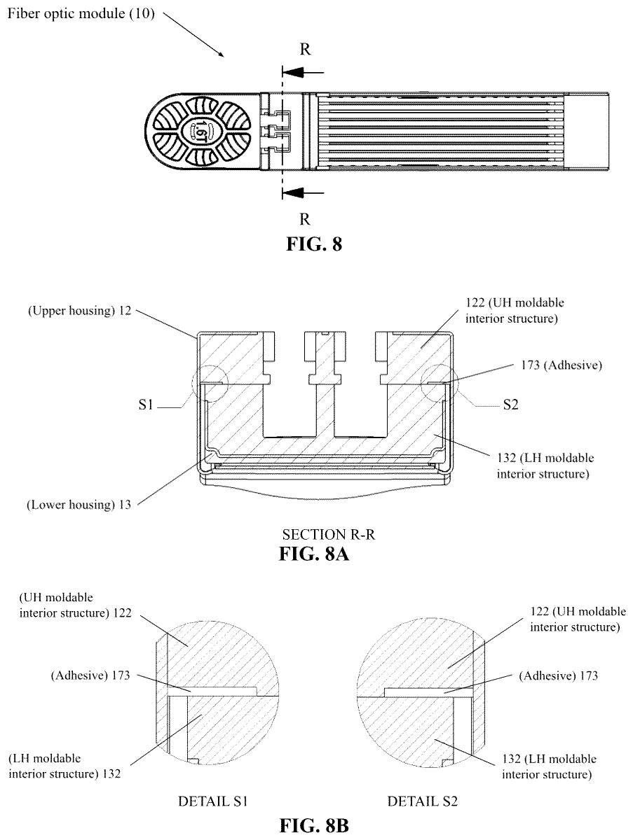

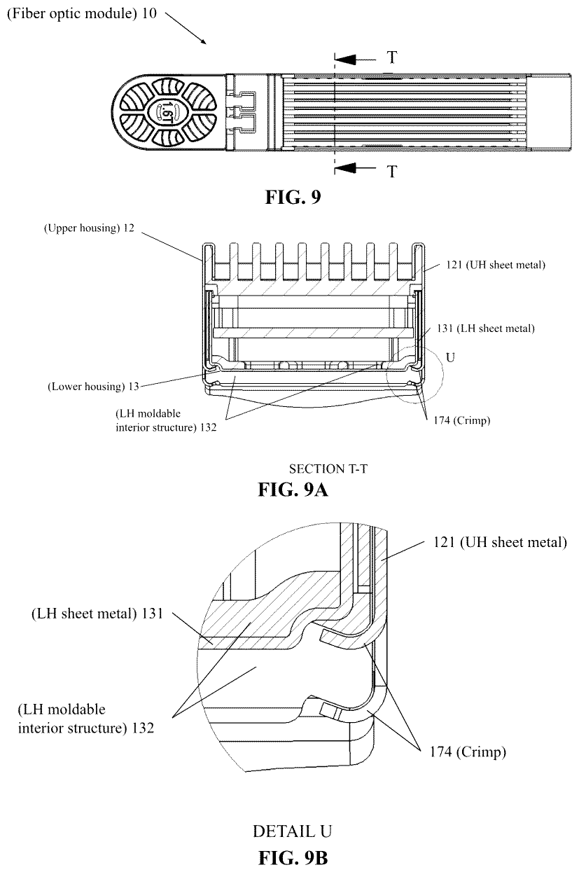

FIG. 8 is a top plane view of the Fiber optic module 10. (Similar views are shown in FIGS. 9, 10, 10D, 10H, 11, 12 13, 13D, 14B, 14F and 14N for ease of reference in discussing other elements of the fiber optic module 10.) FIG. 8A is a sectional view along line R-R in FIG. 8. FIG. 8B is a detailed view of the circled areas labeled S1 and S2 in FIG. 8A showing another method of securing the components of the UH 12 to the LH 13. A line of thermoplastic or thermoset adhesive 173 placed between the UH moldable interior structure 122 and the LH moldable interior structure 132 is used to affix the upper housing 12 to the lower housing 13 of the fiber optic module 10. Alternative methods of joining the upper housing 12 and the lower housing 13 the adhered surfaces may include interlocking or geometric restraint features that inhibit relative movement not only in planes orthogonal to the adhesive interface but also across a range of non-coplanar vectors. These features are configured to resist shear forces acting on the Adhesive 173 in any direction deviating from the principal adhesive plane, thereby confining relative motion and distributing/resisting mechanical loads more uniformly throughout the joint. The geometry is optimized to constrain multi-axial displacement, including oblique angles relative to the bond interface, thus enhancing the joint's robustness under complex loading conditions to enhance structural integrity and mitigate shear displacement.

FIG. 9 presents a top plane view of the fiber optic module 10. FIG. 9A is a cross-sectional view taken along line T-T in FIG. 9. FIG. 9B provides a detailed view of the circled area labeled U in FIG. 9A, offering an alternative perspective of the improved assembly and shielding features of the fiber optic module 10. Additionally, FIG. 9B illustrates an alternative assembly method, wherein the upper housing 12 and lower housing 13 of the fiber optic module 10 can be secured through a crimp 174 or a fold at the crimp 174, effectively joining the UH 12 and LH 13. The crimping mechanism serves as a mechanical fastening method that secures the upper housing 12 to the lower housing 13 of the fiber optic module 10. This is achieved by plastically deforming a section of the upper housing 12 or lower housing 13, creating a permanent mechanical interlock without requiring additional fasteners or adhesives.

The crimping process involves applying localized compressive force to the designated crimp 174 region, causing material displacement that mechanically locks the Upper housing 12 and Lower housing 13 together. The deformation can take various forms, including: Interference Crimp: The material of the upper housing 12 partially encapsulates the lower housing 13 or vice versa, creating a secure press-fit. Folded Crimp: A tab or edge of the upper housing 12 is bent over the lower housing 13 or vice versa, forming a mechanical seam that prevents separation. Radial or Peripheral Crimp: The edges of the housing components are circumferentially compressed, ensuring uniform mechanical retention. This crimping method enhances structural integrity, improves shielding effectiveness by maintaining enclosure continuity, and ensures a reliable mechanical connection while minimizing assembly complexity.

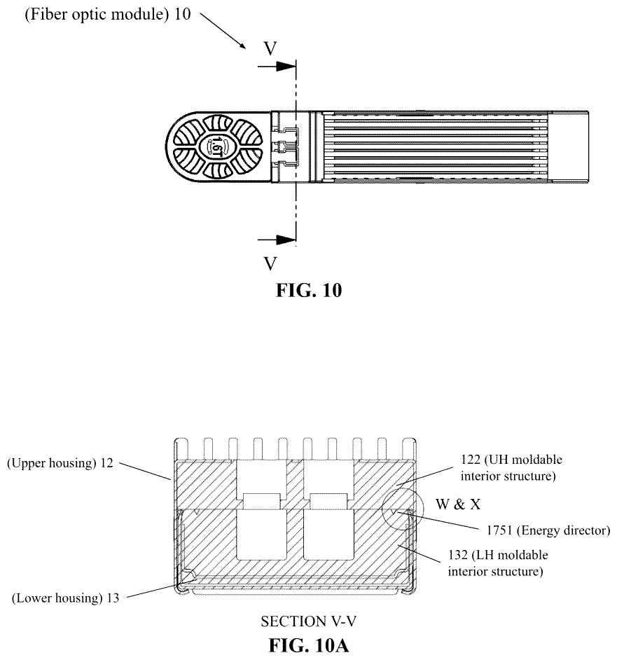

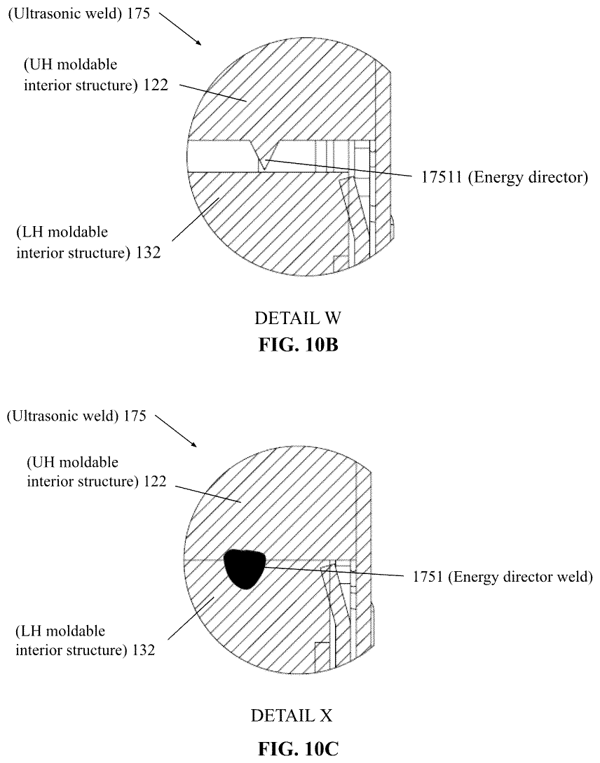

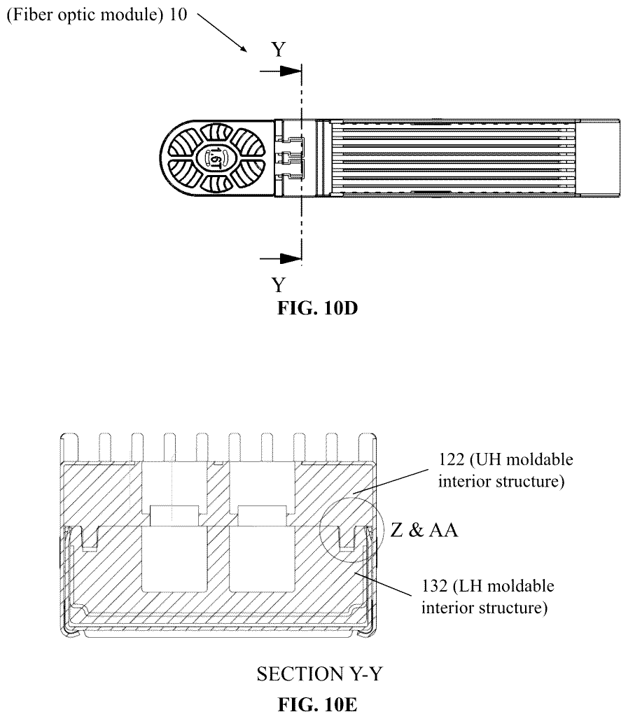

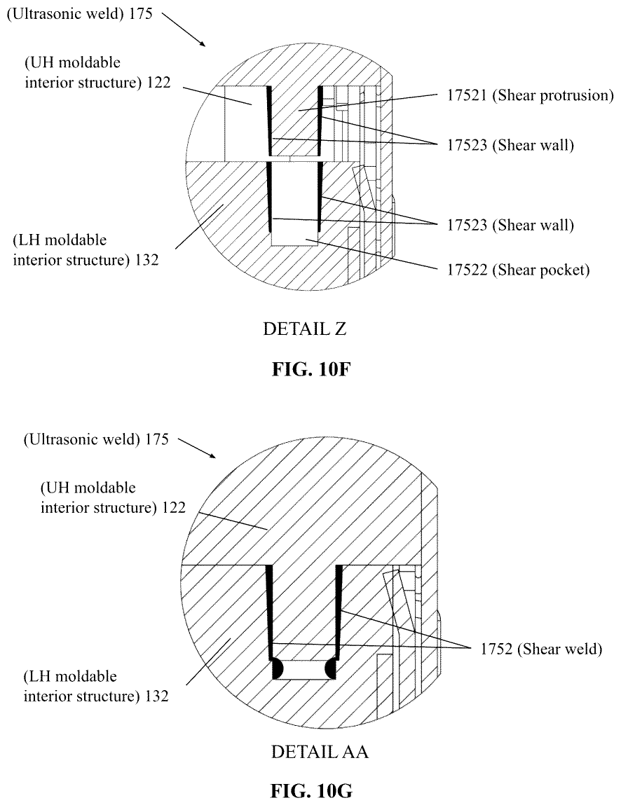

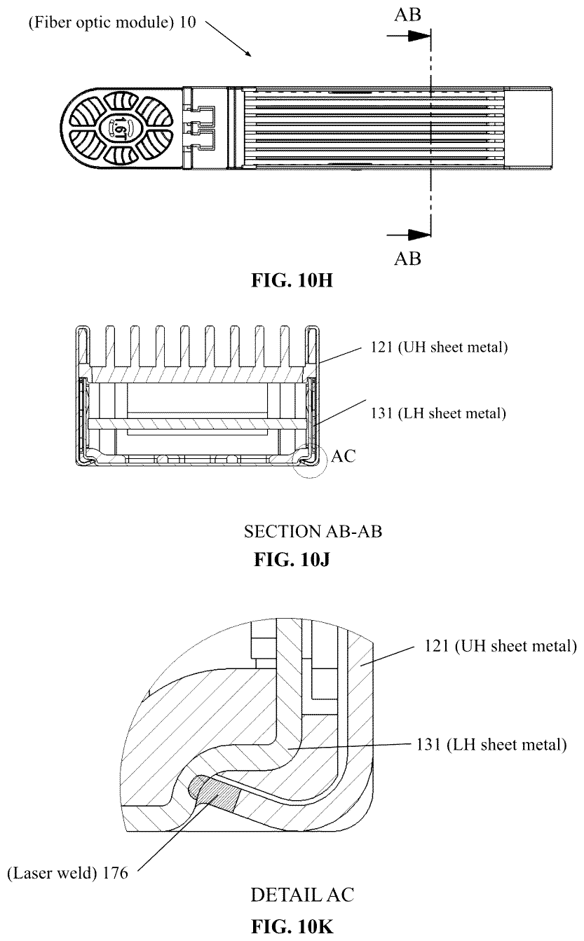

FIG. 10 is a top plane view of an embodiment of a fiber optic module 10. FIG. 10A is a sectional view along line V-V in FIG. 10.

FIG. 10B and FIG. 10C feature a detailed view of the circled areas labeled W and X in FIG. 10A showing another assembly method that can be utilized to secure the UH 12 and LH 13 of the fiber optic module 10. An energy director 17511 feature under pressure and approximately 20 KHz mechanical oscillating vibration of approximately 0.002 in induces frictional heat to fuse the UH moldable interior structure 122 to the LH moldable interior structure 132 forming an energy director weld 1751.

FIG. 10D is a top plane view of an embodiment of a fiber optic module 10. FIG. 10E is a sectional view along line Y-Y in FIG. 10D. showing a shear protrusion 17521 and a shear pocket 17522 where the shear wall 17523 has a 0.002 in to 0.004 in interference fit under pressure and approximately 20 KHz mechanical oscillating vibration of approximately 0.002 in induces frictional heat to fuse the UH moldable interior structure 122 to the LH moldable interior structure 132 forming a shear weld 1752.

FIG. 10H is a top plane view of an embodiment of a fiber optic module 10. FIG. 10J is a sectional view along line AB-AB in FIG. 10H. showing an assembly method that can be utilized to secure the UH 12 and LH 13 of the fiber optic module 10. A laser weld 176 connects the LH 13 to the UH 12 through the UH sheet metal 121 and LH sheet metal 131.

FIG. 11 is a top plane view of an embodiment of a fiber optic module 10. FIG. 11A is a sectional view along line AD-AD in FIG. 11. FIG. 11B features a detailed view of the circled area labeled AE in FIG. 11A showing a coplanar 144 thermal transfer device which may have mirrored concave 1441 and convex 1442 features to accommodate non-coplanar surfaces. The coplanar 144 TTD will of course be constructed from a heat conductive material such as copper. A magnet 1443 is placed in concave 1441 feature, while another magnet 1443 is placed on the convex 1442 to align the surfaces of the coplanar 144 into a neutral position. When assembled, coplanar 144 will conform to the same plane of the heat source 182 mounted on the PCBA 18 with or without a TIM 21. Maintaining correct alignment maximizes the efficiency of the Coplanar 144 so that the thickness of the relatively expensive thermal transfer materials can be minimized. The exact shape of the TTD 14 is chosen to maximize surface area, thereby maximizing heat transfer capability.

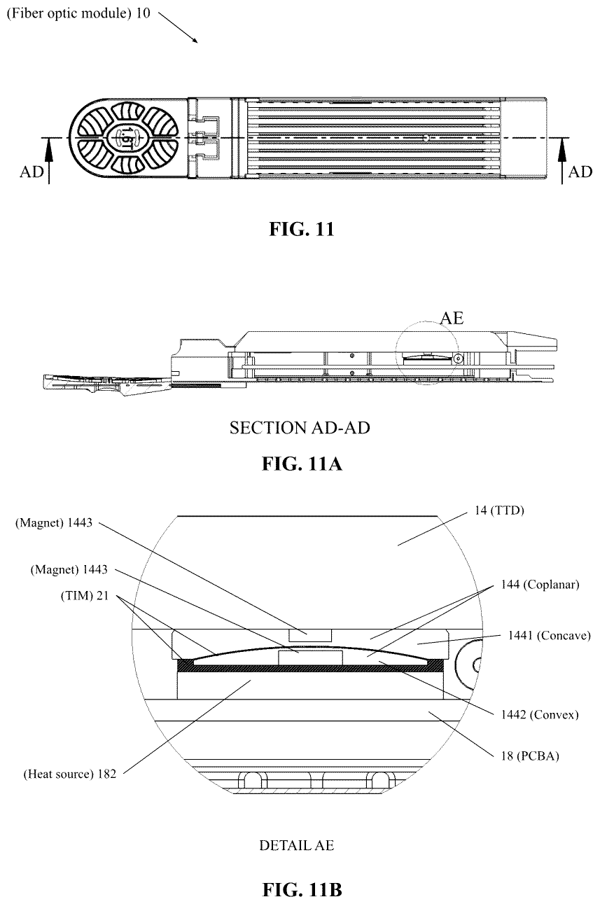

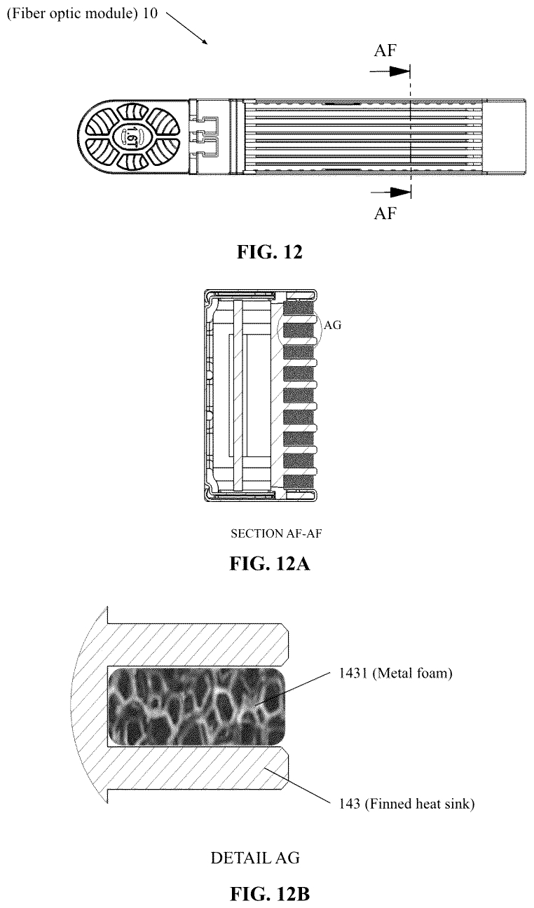

FIG. 12 is a top plane view of an embodiment of a fiber optic module 10. FIG. 12A is a sectional view along line AF-AF in FIG. 12. FIG. 12B is a detailed view of the circled area labeled AG in FIG. 12A. Showing a Metal foam 1431 that may be inserted between the fins of the Finned heat sink 143. Metal foam 1431 is formed from aluminum, aluminum alloy, copper or copper alloy or another heat conductive material. The finned heat sink 143 may be divided into multiple temperature zones by adding thermal insulators between the zones.

In various embodiments of the device, the metal foam 1431 placed between the fins of the finned heat sink 143 is copper foam. The copper foam can be coated with graphene to further optimize heat transfer. The fins on the finned heat sink 143 can also be coated with copper or another metal with high heat conductivity and/or graphene. The coating may also be any of graphene, copper, nickel, or gold, or combinations thereof. In addition to copper foam, aluminum or aluminum foam may be used as the material inserted between the fins of the Finned heat sink 143.

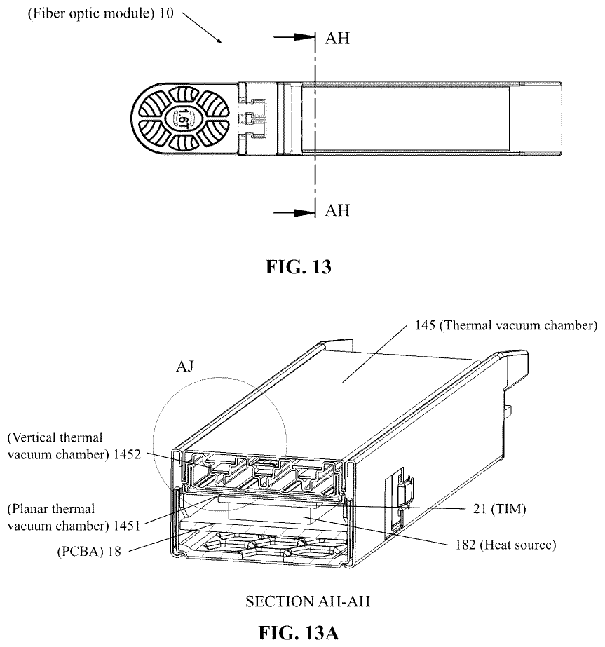

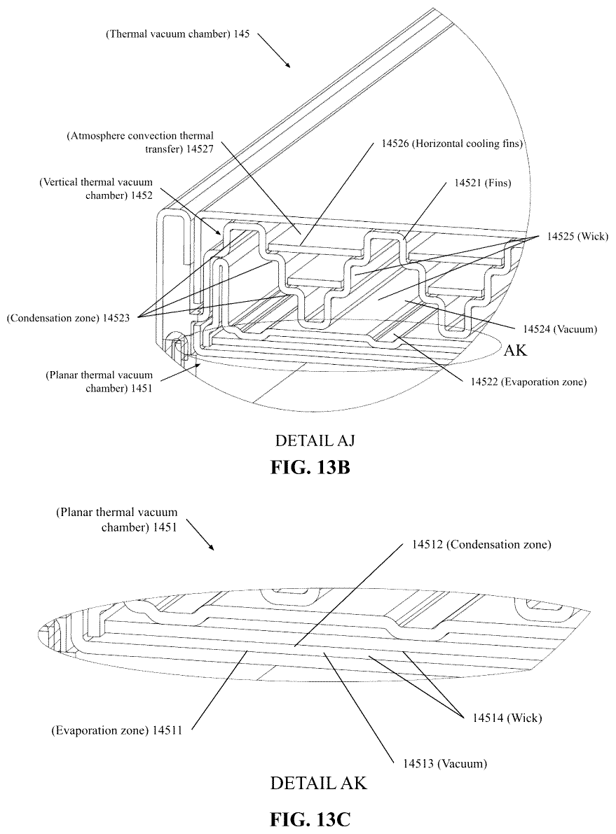

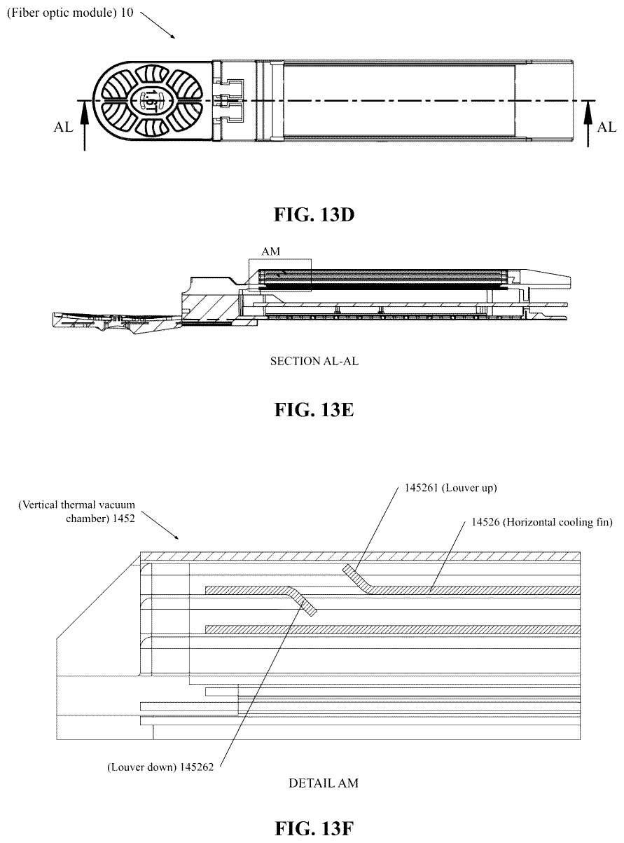

FIG. 13 is a top plane view of the fiber optic module 10. FIG. 13A is a sectional view along line AH-AH in FIG. 13. FIG. 13B is a detailed view of the circled area labeled AJ in FIG. 13A. FIG. 13C is a detailed view of the circled area labeled AK in FIG. 13B. showing another method of providing heat dissipation in the fiber optic module 10. In various embodiments utilizing this conformation, the fiber optic module 10 is formed with a Thermal vacuum chamber 145 construction. A thermal vacuum chamber 145 is a thermal transfer device for enhanced cooling performance. The thermal vacuum chamber 145 operates based on the principle of phase change, where a working fluid inside a sealed vacuum chamber absorbs heat from a Heat source 182 mounted on a PCBA 18, vaporizes, and then travels to a cooler area where it condenses back into a liquid, releasing the absorbed heat. This continuous cycle enables rapid and uniform heat dissipation, making the vapor chamber an ideal solution for high-performance thermal management applications.

The thermal vacuum chamber 145 construction includes an area serving as a planar thermal vacuum chamber 1451 and/or a vertical thermal vacuum chamber 1452 with inner walls that are lined with a porous wicking material wick 14525. These chambers contain a specified amount of working fluid at a specified vacuum level. The vacuum environment significantly reduces the boiling point of the working fluid, enabling it to evaporate at lower temperatures. This characteristic enhances the chamber's thermal efficiency by promoting faster and more efficient phase transitions.

Heat is generated from the primary heat source 182, such as an IC mounted on a PCBA 18. A thermal interface material (TIM) 21 is applied between the heat source 182 and the planar thermal vacuum chamber 1451 to ensure efficient thermal transfer by minimizing resistance. When heat is applied to the planar thermal vacuum chamber 1451, the fluid in contact with the heat source 182 evaporates rapidly, creating vapor within the evaporation zone 14522. The generated vapor, driven by pressure differences, spreads across the plane towards cooler areas, such as the condensation zone 14523.

Upon reaching the condensation zone 14523 of the chamber, the vapor condenses back into liquid form. The condensed liquid is then drawn back to the heat source via the wicking structure through capillary action, ensuring a continuous thermal cycle. This cycle provides consistent heat dissipation.

Heat is then further transferred to the vertical thermal vacuum chamber 1452, which enhances heat dissipation by utilizing an array of fins 14521 to increase surface area. The evaporation and condensation cycle repeats in the vertical thermal vacuum chamber 1452.

Finally, accumulated heat is carried away by convection through the cooling vertical thermal vacuum chamber 1452. Horizontal cooling fins 14526 increase surface area and dissipate heat into the surrounding atmosphere via atmosphere convection thermal transfer 14527.

FIG. 13D is a top plane view of another embodiment of the fiber optic module 10. FIG. 13E is a sectional view along line AL-AL in FIG. 13D. FIG. 13F is a detailed view of the square area labeled AM in FIG. 13E showing vertical thermal vacuum chamber 1452, and including horizontal cooling fin 14526, and includes built in louver up 145261 and louver down 145262 to increase or decrease the airflow velocity and direct the airflow to different thermal zones.

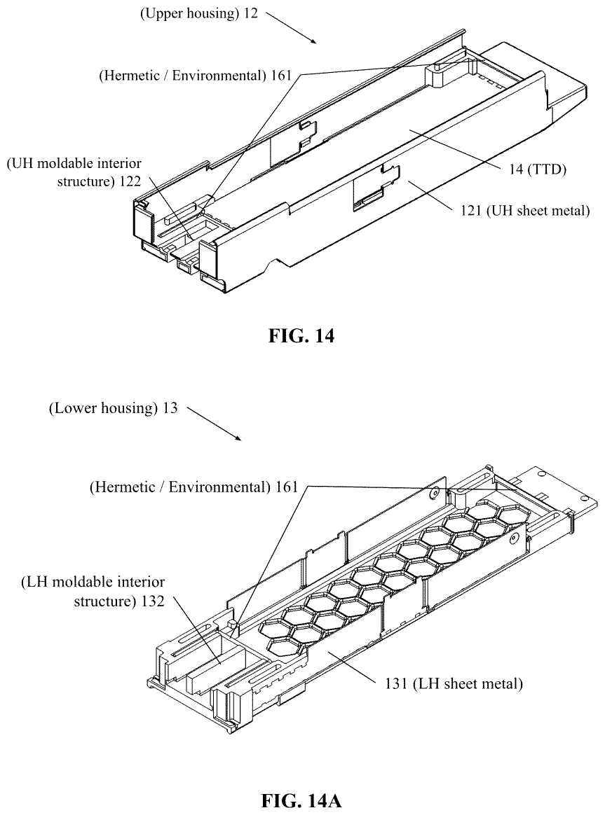

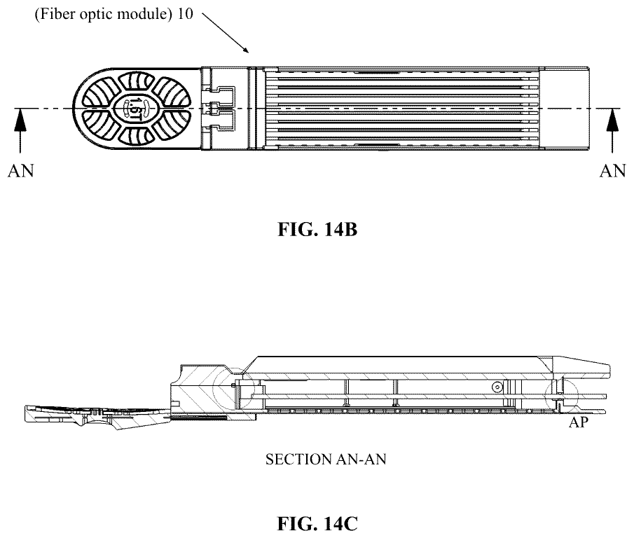

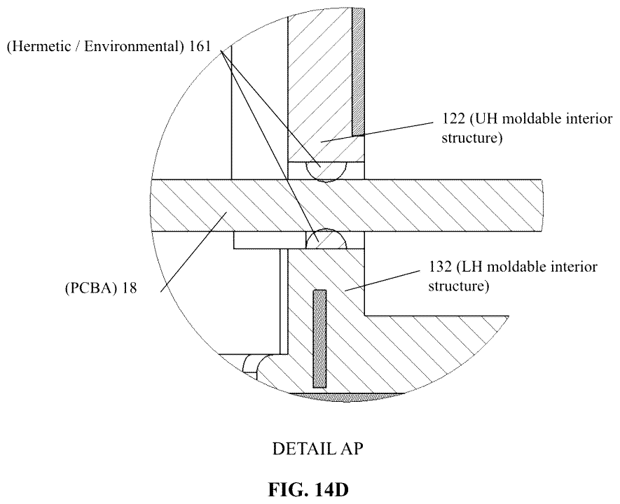

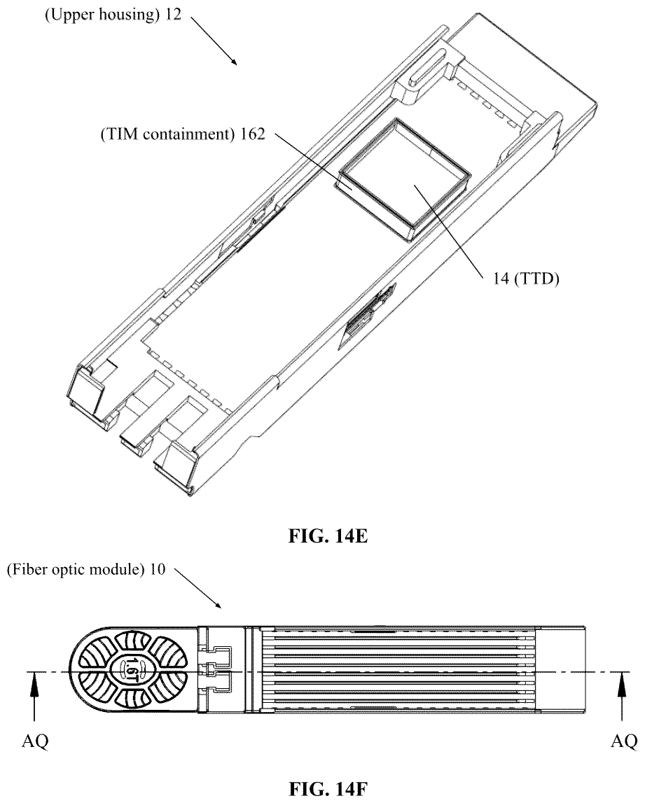

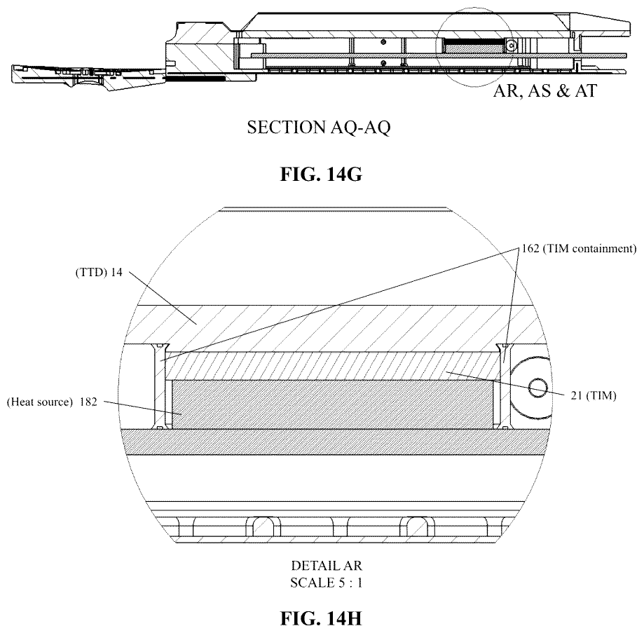

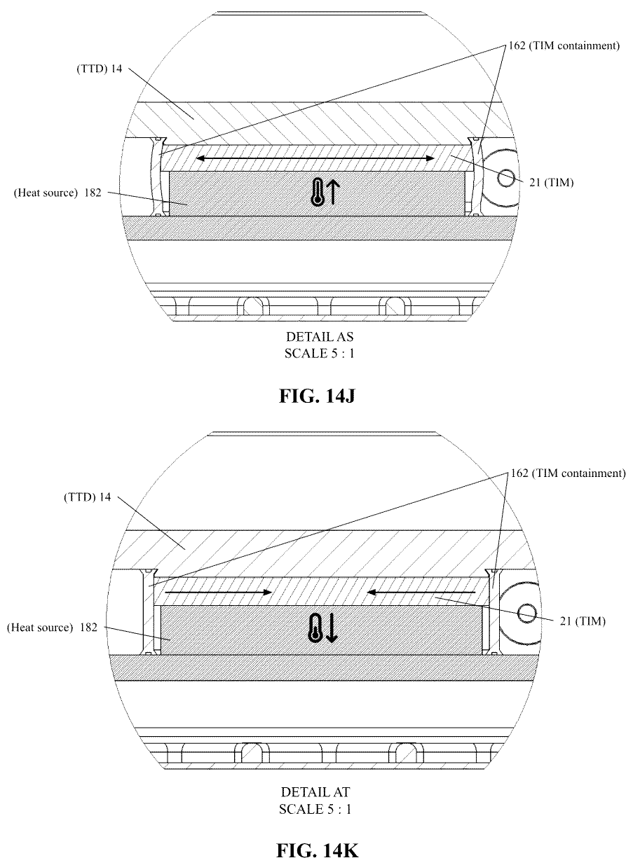

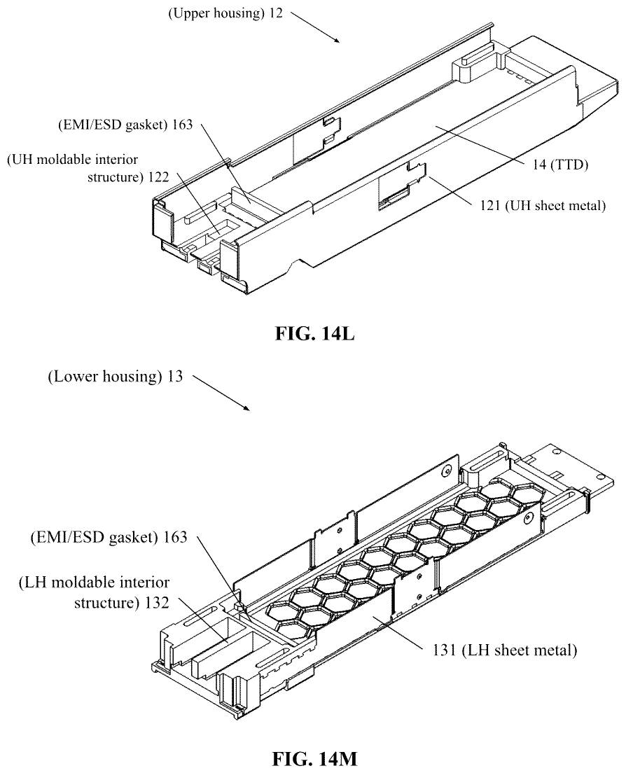

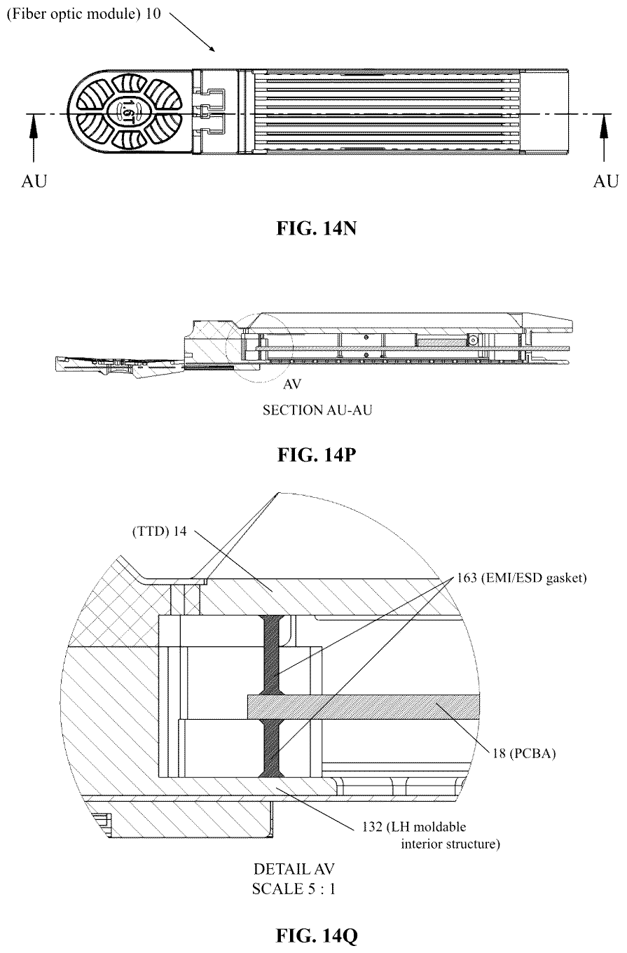

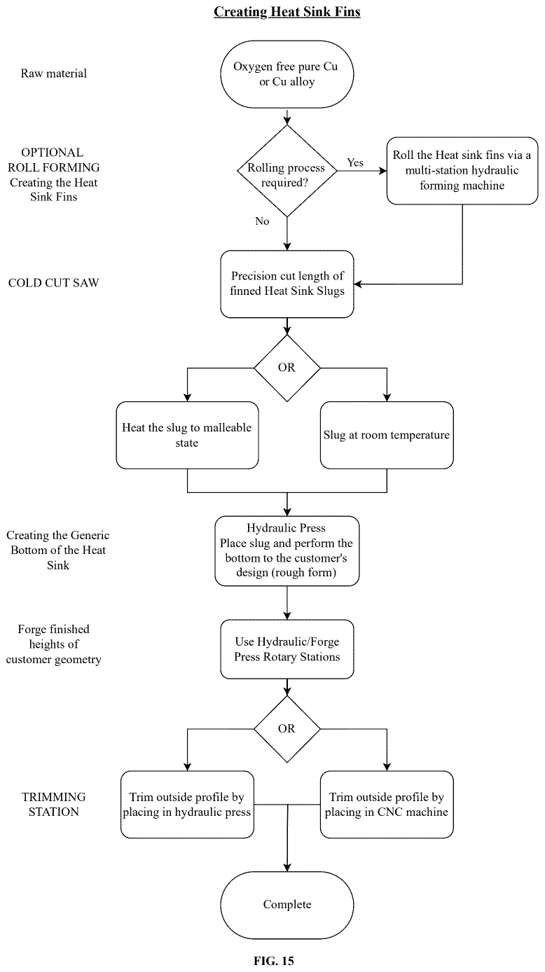

FIG. 14 is a perspective bottom view of an embodiment of an upper housing 12 where a hermetic/environmental 161 seal is placed directly on the UH moldable interior structure 122 and/or the UH sheet metal 121 and optionally to the TTD 14.

FIG. 14A is a perspective view of an embodiment of a lower housing 13 where a hermetic/environmental 161 seal is placed directly on the LH moldable interior structure 132 and/or the LH sheet metal 131 or optionally to a TTD 14.

FIG. 14B is a top plane view of another embodiment of the fiber optic module 10. FIG. 14C is a sectional view along line AN-AN in FIG. 14B. FIG. 14D is a detailed view of the circled area labeled AP in FIG. 14C showing hermetic/environmental 161 seals placed between PCBA 18, UH moldable interior structure 122 and LH moldable interior structure 132 to create an effective physical barrier separating the interior of the fiber optic module 10 to the external environment.

FIG. 14E is a perspective view of an embodiment of an upper housing 12 showing the TIM containment 162 surrounding the TTD 14. FIG. 14F is a top plane view of an embodiment of a fiber optic module 10 comprising the upper housing 12 of FIG. 14E.

FIG. 14G is a sectional view along line AQ-AQ in FIG. 14F. FIG. 14H is a detailed view of the circled area labeled AR in FIG. 14G. showing a flexible perimeter wall, TIM containment 162, forming a pliable structure to contain a semi-liquid/plastic TIM 21. TIM containment 162 is positioned between the top surface of the heat source 182 and the bottom surface of the TTD 14 around the perimeter of the heat source 182 and TIM 21. The flexible wall design provides a cycle expandable then compressible, adaptable barrier that contains the TIM 21.

FIG. 14J is a detailed view of circled area labeled AS in FIG. 14G. which illustrates that during the heat cycle of the heat source 182 and its expansion, compressing the TIM 21 pressed against the adaptable barrier of TIM containment 162, preventing the material from being squeezed out.

FIG. 14K is a detailed view of the circled area labeled AT in FIG. 14G which illustrates that during the cooling cycle of the heat source 182 and its contraction of the TIM 21, the adaptable barrier of TIM containment 162 pushes the TIM 21 back into the gap between the Heat source 182 and TTD 14, allowing it to conform to surface irregularities and improve heat transfer efficiency while preventing TIM 21 pumping/wicking out. This invention allows for thinner and lower viscosity TIM 21.

FIG. 14L is a bottom perspective view of an embodiment of an upper housing 12 showing the EMI/ESD gasket 163 placed in either the TTD 14, UH moldable interior structure 122 or UH sheet metal 121 or a combination there of.

FIG. 14M is a perspective view of an embodiment of a lower housing 13 showing the EMI/ESD gasket 163 placed in either the LH moldable interior structure 132, LH sheet metal 131, TTD 14 or a combination thereof.

FIG. 14N is a top plane view of an embodiment fiber optic module 10. FIG. 14P is a sectional view along line AU-AU in FIG. 14N. FIG. 14Q is a detailed view of the circled area labeled AV in FIG. 14P showing EMI/ESD gasket 163, placed between PCBA 18, TTD 14 and LH moldable interior structure 132 or a combination thereof.

The general process of preparing heat sink elements, and in particular the finned heat sink 143, is outlined in FIG. 15. The raw material typically copper or copper alloy may be aluminum or aluminum alloys stock. The material may be roll formed or pressed through near net shape processes to create multiple fins and the required two dimensional and three dimensional features. The material may be heated if desired to make it more malleable. The process may require one or more stations to achieve the desired features.

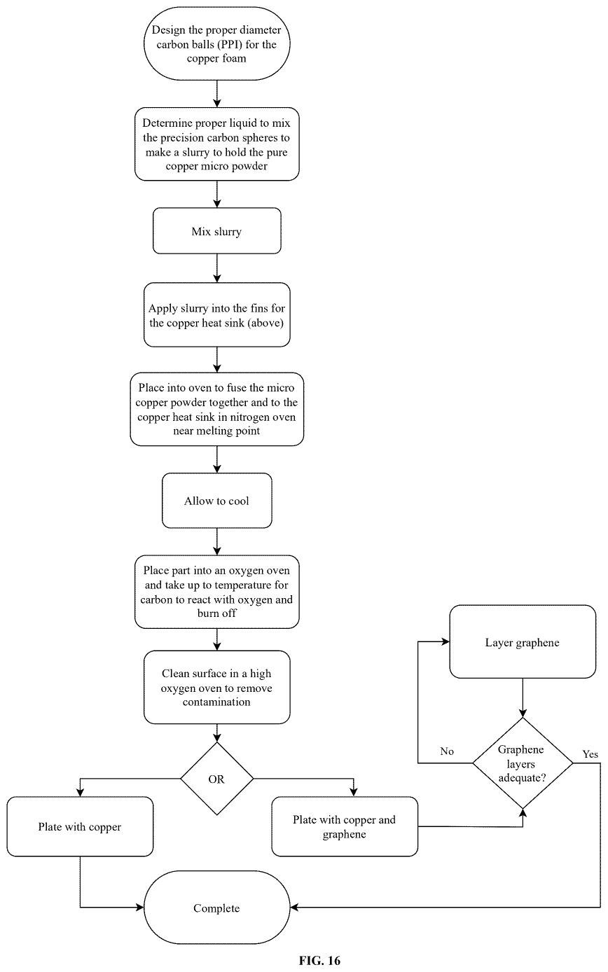

The process to prepare the metal foam 1431 that is inserted between the fins of the finned heat sink 143 is outlined in the flow chart in FIG. 16. Generally, the inserted material is prepared by mixing precision micro carbon balls in a slurry with nearly pure copper or copper alloy micro powder. The liquid used for the slurry is an organic material that binds the carbon balls and copper together while fusing the copper micro-powder. Liquids suitable for the process may be chosen from water, mineral spirits, paraffin, glycerin, and glycerol. The process occurs at a temperature at which the copper is plastic.

The slurry is then applied to the projections (fins) of the finned heat sink 143. The finned heat sink 143 is then baked in a nitrogen oven to plasticize and fuse the metal in the slurry so that it adheres to the surface of the finned heat sink 143. The finned heat sink 143 is then heated in an oxygen oven to burn off the carbon from the slurry. The finned heat sink 143 surface is then cleaned to remove any contamination. If desired by the user, the finned heat sink 143 may then be plated with copper or graphene (one or more layers) or a combination of the two.

The individual steps of the process are as follows:
1. The solution is mixed with an organic compound into the carbon spheres to remove the gases in the porous carbon spheres, which could create casting defects for later steps.
2. Then, mix the Cu or Al Micro Powder with the paraffin carbon spheres above, creating the casting material.
3. The following process set requires a Cu or Al heat sink to be loaded into a mold. The Cu or Al Foam casting material is heated to a temperature where the paraffin is fluid but viscous to hold the uniform binding of the Cu or Al micro-powder and the paraffin-loaded carbon spheres together but pliable enough to apply the paste between the Cu or Al heat Sink thermal fins loaded into the mold.
4. The mold is placed into an oxygen-free oven to fuse the Cu or Al paste to the Cu or Al heat sink. There may be pressure in the molded casting mixture mentioned above. May include additional micro powder to press down through the matrix as the phase changes and the binding of the micro powder will reduce the volumetric space occupied during the process. The Paraffin will evaporate in the oven due to the temperature and lack of Oxygen. There will be enough pressure on the matrix to keep the Carbon Spheres in place and suspended through the process, where they will hold and counter the separation due to density differential and the effects of the forces applied by gravity. With less pressure required to crush or break the carbon spheres. The key here is the pressure and oxygen-free furnace to prohibit the organic or carbon from combusting and the temperature to achieve the plastic state of Cu or Al at a temperature near 1084 degrees C. for Cu and near 660 degrees C. for Al.
5. Cool the fused Cu Foam in the Heat sink mold to room temperature.
6. Place the sample into an oxygen and temperature-controlled oven at the right temperature to burn off the carbon spheres and paraffin binder used to bond the fused Cu, Al, Cu alloy or Al alloy micro-powder. The oven will be at a much lower temperature than the fusing, and the reactions will release carbon dioxide and water vapors.

The description of the present disclosure has been presented for purposes of illustration and description, but is not intended to be exhaustive or limited to the present disclosure in the form disclosed. Many modifications and variations will be apparent to those of ordinary skill in the art without departing from the scope and spirit of the present disclosure. Exemplary embodiments were chosen and described in order to best explain the principles of the present disclosure and its practical application, and to enable others of ordinary skill in the art to understand the present disclosure for various embodiments with various modifications as are suited to the particular use contemplated.

While this technology is susceptible of embodiment in many different forms, there is shown in the drawings and will herein be described in detail several specific embodiments with the understanding that the present disclosure is to be considered as an exemplification of the principles of the technology and is not intended to limit the technology to the embodiments illustrated.

The terminology used herein is for the purpose of describing particular embodiments only and is not intended to be limiting of the technology. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that like or analogous elements and/or components, referred to herein, may be identified throughout the drawings with like reference characters. It will be further understood that several of the figures are merely schematic representations of the present disclosure. As such, some of the components may have been distorted from their actual scale for pictorial clarity.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” or “according to one embodiment” (or other phrases having similar import) at various places throughout this specification are not necessarily all referring to the same embodiment. Furthermore, the particular features, structures, or characteristics may be combined in any suitable manner in one or more embodiments. Furthermore, depending on the context of discussion herein, a singular term may include its plural forms and a plural term may include its singular form. Similarly, a hyphenated term (e.g., “on-demand”) may be occasionally interchangeably used with its non-hyphenated version (e.g., “on-demand”), a capitalized entry (e.g., “Software”) may be interchangeably used with its non-capitalized version (e.g., “software”), a plural term may be indicated with or without an apostrophe (e.g., PE's or PEs), and an italicized term (e.g., “N+1”) may be interchangeably used with its non-italicized version (e.g., “N+1”). Such occasional interchangeable uses shall not be considered inconsistent with each other.

It is noted at the outset that the terms “coupled,” “connected”, “connecting,” “electrically connected,” etc., are used interchangeably herein to generally refer to the condition of being electrically/electronically or optically connected. Similarly, a first entity is considered to be in “communication” with a second entity (or entities) when the first entity electrically sends and/or receives (whether through wireline or wireless means) information signals (whether containing data information or non-data/control information) to the second entity regardless of the type (analog or digital) of those signals. It is further noted that various Figures (including component diagrams) shown and discussed herein are for illustrative purposes only, and are not drawn to scale.

While specific embodiments of, and examples for, the system are described above for illustrative purposes, various equivalent modifications are possible within the scope of the system, as those skilled in the relevant art will recognize. For example, while processes or steps are presented in a given order, alternative embodiments may perform routines having steps in a different order, and some processes or steps may be deleted, moved, added, subdivided, combined, and/or modified to provide alternative or sub-combinations. Each of these processes or steps may be implemented in a variety of different ways. Also, while processes or steps are at times shown as being performed in series, these processes or steps may instead be performed in parallel, or may be performed at different times.

What is claimed is:

1. A fiber optic module housing comprising:
a sheet metal exoskeleton formed with at least one fold, the exoskeleton having an outer surface that defines the device's primary exterior dimensions and provides structural strength; and
an interior geometry formed within the exoskeleton wherein the geometry is established by the negative features of a mold cavity that impart the desired shape to a moldable material during the forming process. ; wherein the moldable material transitions from any of a liquid to solid state, semi-liquid to solid state, a first solid state to a second solid state, and wherein, once the moldable material is shaped, the moldable material remains secured to the exoskeleton, leaving behind a defined three-dimensional geometry that provides alignment for components of the fiber optic module.

2. The housing according to claim 1, wherein the moldable material is formed integrally with the exoskeleton.

3. The device according to claim 1, wherein the sheet metal exoskeleton is formed from a material selected from the group consisting of stainless steel, copper or a copper alloy, aluminum or an aluminum alloy, and a cladding comprising any combination of the above materials.

4. The device according to claim 1, wherein the moldable material is selected from the group consisting of a polymer, zinc or a zinc alloy, aluminum or an aluminum alloy, a die-cast zinc or zinc alloy, a die-cast aluminum or aluminum alloy, a molded element, a cast element, a die cast element, a forged element, a hydraulically formed element, or a metal injection molded element.

5. The device according to claim 4, wherein the moldable material comprises a polymer combined with at least one additive selected from the group consisting of minerals with fire-inhibiting properties, metal flakes or metal spheres for ESD/EMI diffusion, absorption, or reduction, and carbon for structural strength, conductivity, and ESD/EMI diffusion, absorption, or reduction, the moldable material being treated with a plasma vapor deposition process to make the non conductive surfaces conductive, thereby providing additional electromechanical interference/electrostatic discharge protection.

6. The device according to claim 1, further comprising a release mechanism that includes at least one sidewall with an integrated spring and cam.

7. The housing according to claim 6, wherein the release mechanism further comprises at least one of a slide guide; a spring-biased retainer configured to hold the slide release mechanism in a latch-engaged position, wherein pulling the release mechanism drives a cam from the latch-engaged position to a disengaged position; a member on a distal end configured to retain the release mechanism on the housing; and a member configured to limit movement of the release mechanism to the latch-engaged position and disengaged position.

8. The device according to claim 7, wherein a cam geometry is formed from sheet metal having two parallel planes, a top plane and a bottom plane; and an adjoining plane between the top plane and the bottom plane, the adjoining plane forming a ramp with at least one sidewall at one edge of the ramp between the top plane and bottom plane to provide structural support for thinner materials.

9. The device according to claim 1, wherein the upper housing, the lower housing, and a release mechanism each include a side wall, wherein at least a portion of each one of the side walls overlaps with corresponding side walls of the remaining two side walls, thereby providing electromagnetic interference (EMI) shielding and electrostatic discharge (ESD) protection along the sides of the fiber optic module.

10. The device according to claim 1, further comprising a thermal transfer device adapted to remove heat from the fiber optic module, wherein the thermal transfer device is mounted in an opening in the housing or is integrated into the housing as part of the moldable material.

11. The device according to claim 10, wherein the thermal transfer device is formed of at least one solid material selected from the group consisting of copper, a copper alloy, aluminum, and an aluminum alloy.

12. The device according to claim 10, wherein the thermal transfer device is finned.

13. The device according to claim 12, further comprising a porous thermally conductive material inserted between at least two fins of the thermal transfer device.

14. The device according to claim 13, wherein the porous thermally conductive material is selected from the group consisting of copper foam, copper alloy foam, aluminum foam, or aluminum alloy foam.

15. The device according to claim 14, wherein the porous thermally conductive material is coated with graphene.

16. The device according to claim 14, wherein carbon nanotubes are grown inside the porous thermally conductive material.

17. The device according to claim 10, wherein the thermal transfer device is a thermal vacuum chamber formed of copper, a copper alloy, aluminum, or an aluminum alloy.

18. The device according to claim 17, wherein the thermal vacuum chamber is planar.

19. The device according to claim 17, wherein the thermal vacuum chamber is vertically oriented to remove the heat from a heat source and transfer it to the atmosphere.

20. The device according to claim 10, wherein the thermal transfer device comprises an integral device including at least one concave or convex surface adapted to align a non-coplanar top of a heat source to the at least one concave or convex surface.

21. The device according to claim 10, wherein:
The inset device includes at least a pair of magnets to aid positioning of the thermal transfer device so that the surfaces of a heat source remain aligned with surfaces of the heat sink.

22. The device according to claim 12, further comprising at least one horizontal cooling fin placed between two vertical thermal fins to increase surface area.

23. The device according to claim 10, further comprising at least one opening configured to direct airflow and to control airflow velocity across the finned heat sink.

24. The device according to claim 1, further comprising an alignment element coupled with an interference fit between a protrusion element and a corresponding pocket element, each of the elements being formed from the moldable material and configured to hold internal components within a preassembled housing for testing prior to final assembly.

25. The device according to claim 1, wherein the upper housing is affixed to the lower housing by at least one fastening method selected from the group consisting of mechanical fasteners, adhesives, metal crimping, ultrasonic welding, friction welding, and laser welding.

26. The device according to claim 1, wherein molded liquid silicone rubber (LSR) or LSR compounded with metal flakes forms at least one of a hermetic or environmental seal, a thermal interface material (TIM) containment seal, and an electromagnetic interference/electrostatic discharge (EMI/ESD) seal.
